(19) United States
(12) Patent Application Publication
(10) Pub. No.: US 2026/0333577 A1
(43) Pub. Date: Oct. 22, 2026

(54) CIRCUIT BOARD AND SEMICONDUCTOR PACKAGE COMPRISING SAME

(71) Applicant: LG INNOTEK CO., LTD., Seoul (KR)

(72) Inventors: Se Woong NA, Seoul (KR); Kee Han LEE, Seoul (KR)

(73) Assignee: LG INNOTEK CO., LTD., Seoul (KR)

(21) Appl. No.: 19/109,617

(22) PCT Filed: Sep. 7, 2023
(86) PCT No.: PCT/KR2023/013455

§ 371 Date: Mar. 7, 2025

(30) Foreign Application Priority Data
Sep. 7, 2022 (KR) 10-2022-0113741

(51) Int. Cl. H05K 1/11; H05K 1/181; H05K 1/185

(52) U.S. Cl. CPC H05K 1/111; H05K 1/181; H05K 1/185; H05K 2201/10515; H05K 2201/10522; H05K 2201/10734

(57) ABSTRACT

A circuit board according to an embodiment includes an insulating layer; a first pad disposed on an upper surface of the insulating layer; and a first protective layer disposed on an upper surface of the insulating layer and having an opening overlapping the first pad in a vertical direction, and wherein the opening of the first protective layer includes a region having a width in a horizontal direction greater than a width in the horizontal direction of the first pad, and wherein the first protective layer is provided to cover at least a portion of a side surface of the first pad.

### TECHNICAL FIELD

An embodiment relates to a circuit board and a semiconductor package including the same.

### BACKGROUND ART

In general, a printed circuit board (PCB) is a laminated structure in which insulating layers and conductor layers are alternately laminated, and the conductor layers can be formed into a circuit pattern by patterning.

A printed circuit board such as this is provided with a solder resist (SR) that protects a circuit formed at at outermost side of the laminated structure, prevents oxidation of the conductor layer, and also acts as an insulator when electrically connecting to a chip or other substrate mounted on the printed circuit board.

A typical solder resist forms an opening region (SRO: Solder Resist Opening) that becomes an electrical connection path by combining connecting means such as solder or bumps. In addition, as printed circuit boards become more high-performance and denser, I/O (Input/Output) performance improves, which requires a greater number of solder resist opening regions, and thus requires a smaller bump pitch of the opening region. At this time, the bump pitch of the opening region means a center distance between adjacent opening regions.

Meanwhile, the opening region (SRO) of the solder resist includes a SMD (Solder Mask Defined type) type and a NSMD (Non-Solder Mask Defined Type) type.

The SMD type is characterized by a width of the opening region (SRO) being smaller than a width of a pad exposed through the opening region (SRO), and thus, at least a part of an upper surface of the pad in the SMD type is covered by the solder resist.

In addition, the NSMD type is characterized by a width of the opening region (SRO) being greater than a width of the pad exposed through the opening region (SRO), and thus, the solder resist in the NSMD type is disposed at a certain distance from the pad, and thus, both the upper surface and side surface of the pad are exposed.

However, in a case of the SMD type, after the semiconductor package is bonded to a main board, there is a problem in that a solder ball is separated from the pad exposed through the opening region (SRO) during a solder ball joint reliability test for a bonding strength of the solder ball. In addition, in the case of the NSMD type, there is a problem in that the pad on which the solder ball is disposed is separated from a substrate.

### DISCLOSURE

### Technical Problem

The embodiment provides a circuit board having a novel structure and a semiconductor package including the same.

In addition, the embodiment provides a circuit board including a protective layer having an opening of a step structure and a semiconductor package including the same.

In addition, the embodiment provides a circuit board capable of increasing a contact area between a connecting member and a pad and a semiconductor package including the same.

In addition, the embodiment provides a circuit board capable of improving physical and/or electrical reliability of a metal bonding layer (IMC) between a pad and a connecting member and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises an insulating layer; a first pad disposed on an upper surface of the insulating layer; and a first protective layer disposed on an upper surface of the insulating layer and having an opening overlapping the first pad in a vertical direction, and wherein the opening of the first protective layer includes a region having a width in a horizontal direction greater than a width in the horizontal direction of the first pad, and wherein the first protective layer is provided to cover at least a portion of a side surface of the first pad.

In addition, the circuit board further comprises a second pad disposed on a lower surface of the insulating layer; and a second protective layer disposed on the lower surface of the insulating layer and including an opening overlapping the second pad in the vertical direction.

In addition, the first pad includes a plurality of first pads, and wherein a separation distance between the plurality of first pads satisfies a range of 20% to 90% of a width of each of the plurality of first pads.

In addition, the width of the region of the opening of the first protective layer satisfies a range of 105% to 150% of the width of the first pad.

In addition, the first protective layer includes a side wall forming the opening and a bottom surface of the opening connected to the side wall, and the bottom surface is positioned lower than an upper surface of the first pad and higher than a lower surface of the first pad.

In addition, the first protective layer includes a concave portion provided between the side wall and the bottom surface and concaved toward an inner direction of the first protective layer away from the first pad.

In addition, the first protective layer includes an inclined wall provided between the side wall and the bottom surface and inclined toward an outer surface of the first pad as it approaches the bottom surface from the side wall.

In addition, a vertical distance from a lower surface of the first protective layer to the bottom surface satisfies a range of 20% to 90% of a thickness of the first pad.

In addition, a separation distance in the horizontal direction between a side wall of the opening of the first protective layer from an outer surface of the first pad satisfies a range of 5% to 45% of a spacing between the plurality of first pads.

In addition, the opening of the first protective layer has a step whose width changes along the vertical direction.

In addition, the opening of the first protective layer includes a first part adjacent to the upper surface of the first protective layer and having a width greater than a width of the first pad, and a second part provided under the first part and having a width smaller than the width of the first pad.

In addition, the opening of the first protective layer includes a first part adjacent to the upper surface of the first protective layer and having a width greater than the width of the first pad, and a second part provided under the first part and having a width greater than the width of the first pad and smaller than the width of the first part.

In addition, a step portion between the first part and the second part is positioned higher than an upper surface of the first pad.

In addition, a vertical distance from a lower surface of the first protective layer to the step portion satisfies a range of 110% to 140% of a thickness of the first pad.

In addition, the first protective layer includes a first protective member disposed on the insulating layer; and a second protective member disposed on the first protective member, wherein the first part of the opening is provided in the first protective member, and the second part of the opening is provided in the second protective member.

In addition, a thickness of the first layer of the first protective layer is greater than a thickness of the first pad, and an upper surface of the first layer of the first protective layer is positioned higher than an upper surface of the first pad.

Meanwhile, the semiconductor package of the embodiment comprises: an insulating layer; a first circuit layer disposed on one surface of the insulating layer and including a first pad; and a first protective layer disposed on one surface of the insulating layer and including an opening vertically overlapping the first pad and having a step; a second circuit layer disposed on the other surface of the insulating layer and including a second pad; a second protective layer disposed on the other surface of the insulating layer and including an opening vertically overlapping the second pad; a first connecting member disposed on the first pad while filling the opening of the first protective layer; a main board disposed on the first connecting member; a second connecting member disposed on the second pad while filling the opening of the second protective layer; and a semiconductor device disposed on the second connecting member, wherein the opening of the first protective layer includes a first part adjacent to an upper surface of the first protective layer and having a width greater than the width of the first pad, and a second part provided under the first part and having a width smaller than the width of the first part, and at least a portion of a side surface of the first pad is covered with the first protective layer.

In addition, the semiconductor package further includes at least one semiconductor device disposed on the first circuit layer.

In addition, a width of the first pad of the first circuit layer is greater than a width of the second pad of the second circuit layer.

### Advantageous Effects

The circuit board of the embodiment may include a first insulating layer and a first circuit layer disposed on the first insulating layer. The first circuit layer may include a pad in contact with an electrode of the main board. In addition, the circuit board may include an opening disposed on the first insulating layer and vertically overlapping the pad. At this time, the opening may include a region having a width greater than a width of the pad. Furthermore, at least a portion of a side surface of the pad may be covered with a first protective layer.

Therefore, the embodiment may improve a bonding force between the first insulating layer and the first pad as at least a portion of the side surface of the pad is covered with the first protective layer. Furthermore, the embodiment may improve a contact area between a connecting member disposed on the pad and the pad by making at least a portion of the opening have a width greater than the first pad. That is, in a comparative example, a width of the opening was smaller than the width of the pad, and accordingly, the contact area between the pad and the connecting member was smaller than a planar area of the pad.

In contrast, the contact area between the pad and the connecting member in the circuit board of the embodiment is greater than the planar area of the pad. Accordingly, the embodiment can improve the bonding strength between the pad and the connecting member. Accordingly, the embodiment can solve a physical and/or electrical reliability problem of the connecting member being separated from the pad. Accordingly, the embodiment can improve product characteristics of the circuit board. Furthermore, the embodiment can improve a bonding strength with a main board coupled on the circuit board.

Meanwhile, the embodiment can form an opening in the first protective layer through a removal process for thinning a thickness. In addition, since the opening of the first protective layer is formed through a removal process for thinning the thickness, the embodiment can easily adjust a height of a bottom surface of the opening. For example, in a prior art, the opening was formed through an exposure and development process, and it was impossible to adjust the height of the bottom surface of the opening formed thereby. In contrast, the embodiment can easily adjust the height of the bottom surface by forming the opening through a removal process for thinning the thickness.

Therefore, a side wall of the opening of the first protective layer can include a portion having a slope. For example, the first protective layer may be provided between the side wall and the bottom surface of the opening and may include an inclined wall having a certain inclination angle. At this time, the inclined wall may be closer to the pad of the first circuit layer as it moves from the side wall toward the bottom surface. Therefore, the embodiment may improve a flowability of the connecting member in a process of arranging the connecting member, and thus improve the bonding force between the pad and the connecting member.

In addition, the embodiment may have a step in the opening of the first protective layer. Through this, the embodiment may solve a problem of the connecting member disposed in the opening of the first protective layer overflowing. Therefore, the embodiment may further improve the electrical reliability of the circuit board.

Furthermore, a connecting member such as solder is disposed in the opening of the first protective layer. At this time, when the connecting member is disposed on the pad, a metal bonding layer may be formed between the connecting member and the pad. At this time, the embodiment may increase a length of a side wall of the opening between an upper surface of the first protective layer and a metal bonding layer by making the opening of the first protective layer have a step. For example, in the comparative example, the side wall of the opening connecting the upper surface of the protective layer and the metal bonding layer (IMC) had a structure without an inflection point. Accordingly, in the comparative example, in order to increase a distance of the inner wall of the opening between the upper surface of the protective layer and the metal bonding layer (IMC), a thickness of the first protective layer had to be increased.

In contrast, in the embodiment, by forming a step in the opening, the length of the side wall of the opening between the metal bonding layer (IMC) and the upper surface of the first protective layer can be increased without increasing a thickness of the first protective layer, thereby improving physical reliability of the metal bonding layer (IMC).

### DESCRIPTION OF DRAWINGS

FIG. 1 is a cross-sectional view showing a circuit board according to a comparative example.

FIG. 2 is a cross-sectional view showing a circuit board according to a first embodiment.

FIG. 3 is a plan view of a circuit board in a state in which the first protective layer of FIG. 2 is removed.

FIG. 4 is a plan view of the circuit board of FIG. 2.

FIG. 5 is an enlarged view showing a partial region of FIG. 2.

FIG. 6 is a drawing showing a first modified example of the circuit board of FIG. 5.

FIG. 7 is a drawing showing a second modified example of the circuit board of FIG. 5.

FIG. 8 is a cross-sectional view showing a circuit board according to a second embodiment.

FIG. 9 is an enlarged view showing a partial region of FIG. 8.

FIG. 10 is an enlarged view showing a partial region of a circuit board according to a third embodiment.

FIG. 11 is an enlarged view showing a partial region of a circuit board according to a fourth embodiment.

FIG. 12a is a cross-sectional view showing a circuit board according to a fifth embodiment.

FIG. 12b is a cross-sectional view showing a circuit board according to a sixth embodiment.

FIG. 12c is a cross-sectional view showing a circuit board according to a seventh embodiment.

FIG. 13 is a drawing showing a semiconductor package according to a first embodiment.

FIG. 14a is a drawing showing a semiconductor package according to a second embodiment.

FIG. 14b is a drawing showing a semiconductor package according to a third embodiment.

FIG. 14c is a drawing showing a semiconductor package according to a fourth embodiment.

FIG. 15 is a cross-sectional view showing a semiconductor package according to a fifth embodiment.

FIGS. 16 to 24 are drawings for explaining a method for manufacturing a circuit board of the first embodiment shown in FIG. 2 in order of processes.

FIGS. 25 to 28 are drawings for explaining a method for manufacturing a circuit board of the third embodiment shown in FIG. 10 in order of processes.

### BEST MODE

Hereinafter, exemplary embodiments of the present invention will be described in detail with reference to the accompanying drawings, wherein like reference numerals are used to designate identical or similar elements, and redundant description thereof will be omitted. The suffix “module” and “portion” of the components used in the following description are only given or mixed in consideration of ease of preparation of the description, and there is no meaning or role to be distinguished as it is from one another. Also, in the following description of the embodiments of the present invention, a detailed description of related arts will be omitted when it is determined that the gist of the embodiments disclosed herein may be obscured. Also, the accompanying drawings are included to provide a further understanding of the invention, are incorporated in, and constitute a part of this description, and it should be understood that the invention is intended to cover all modifications, equivalents, or alternatives falling within the spirit and scope of the invention.

Terms including ordinals, such as first, second, etc., may be used to describe various components, but the elements are not limited to these terms. The terms are used only for distinguishing one component from another.

When a component is referred to as being “connected” or “contacted” to another component, it may be directly connected or joined to the other component, but it should be understood that other component may be present therebetween. When a component is referred to as being “directly connected” or “directly contacted” to another component, it should be understood that other component may not be present therebetween.

A singular representation includes plural representations, unless the context clearly implies otherwise.

In the present application, terms such as “including” or “having” are used to specify the presence of features, numbers, steps, operations, components, parts, or combinations thereof described in the description. However, it should be understood that the terms do not preclude the presence or addition of one or more other features, numbers, steps, operations, components, parts, or combinations thereof.

Hereinafter, an embodiment of the present invention will be described in detail with reference to the accompanying drawings as follows.

### COMPARATIVE EXAMPLE

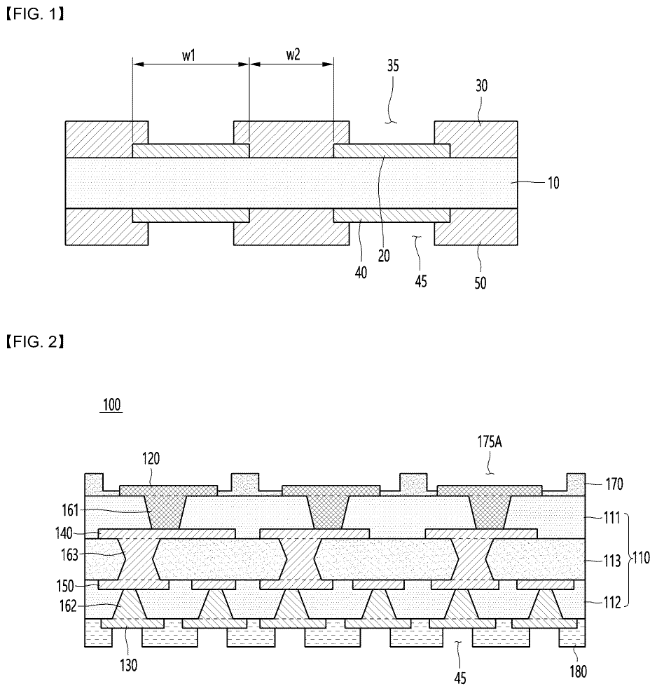

FIG. 1 is a cross-sectional view illustrating a circuit board according to a comparative example.

Referring to FIG. 1, the circuit board of the comparative example includes an insulating layer 10.

Furthermore, the first circuit pattern 20 is disposed on an upper surface of the insulating layer 10. Furthermore, the first circuit pattern 20 includes a pad. Furthermore, the circuit board of the comparative example includes a through electrode penetrating the insulating layer 10. A first protective layer 30 has a first opening 35 overlapping the pad of the first circuit pattern 20 in a vertical direction and disposed on the upper surface of the insulating layer 10.

In this case, the circuit board is coupled to a semiconductor device or an external board. In addition, the pad of the first circuit pattern 20 means a pad coupled to the main board.

Accordingly, the pad of the first circuit pattern 20 has a relatively large width. For example, a width w1 of the pad of the first circuit pattern 20 is 70 μm or more. Also, a spacing w2 between adjacent pads among a plurality of pads is 70 μm or more.

In this case, since the pad has a relatively large width, a first opening 35 of the first protective layer 30 generally has an SMD type. That is, a width of the first opening 35 of the first protective layer 30 is smaller than a width of the pad. Accordingly, at least a portion of the upper surface of the pad is covered with the first protective layer 30 without vertically overlapping the first opening 35.

Meanwhile, recently, an issue has occurred in a coupling force between the circuit board and the main board. Therefore, a size of the connecting member (e.g., solder ball) disposed on the pad for coupling the main board is increasing.

However, the width of the first opening 35 of the first protective layer 30 of the comparative example is smaller than the width of the pad, and accordingly, there is a limit to increasing the contact area between the connecting member and the pad only by increasing the size of the connection member. Accordingly, there is a limit to improving the coupling force between the circuit board and the main board simply by increasing the size of the connecting member.

In this case, a spacing w2 between the pads is relatively large to be more than or equal to 70 μm. Accordingly, a circuit short circuit problem of a plurality of connecting members disposed on pads adjacent to each other may be relatively low. Meanwhile, the size of the connection member is gradually increasing, and accordingly, the amount of the connection member disposed in the first opening 35 of the first protective layer 30 is increasing. Accordingly, when the connection member is disposed in the first opening 35 of the first protective layer 30, the amount of the connection member overflowing to an outside of the first opening 35 of the first protective layer 30 increases. Therefore, a problem of interconnected circuit shorts is occurring due to an increase in the overflow amount of connecting members disposed on pads having a relatively large spacing w2.

Furthermore, when the first opening 35 of the first protective layer 30 is applied as an NSMD type, there is a problem that an adhesion between the insulating layer 10 and the pad decreases as the first protective layer 30 does not contact the pad.

In addition, the circuit board of the comparative example includes a second circuit pattern 40 disposed under the insulating layer 10 and a second protecting 50 disposed under the insulating layer 10 and including a second opening 45 vertically overlapping the second circuit pattern 40.

In this case, the second opening 45 also has an SMD type corresponding to the first opening 35. Accordingly, in the comparative example, there is a problem in that a connection area between the connecting member and the second circuit pattern 40 is reduced, and thus a adhesion between the connecting member and the second circuit pattern 40 is reduced.

Furthermore, when the second opening 45 has the NSMD type, adhesion between the insulating layer 10 and the second circuit pattern 40 may be reduced. Furthermore, the second circuit pattern 40 may be a pad connected to a semiconductor device, and accordingly, may be a fine pattern having a fine line width and a spacing. Accordingly, when the second opening 45 has the SMD type, there is a problem that a contact area with a connection member may not be secured, and when the second opening 45 has the NSMD type, there is a problem that the second circuit pattern 40 is not supported by the second protective layer 50, and thus there is a problem that the second circuit pattern 40 is peeled off from the insulating layer 10.

Hereinafter, a circuit board having a new structure capable of solving the problem of the circuit board of the comparative example as described above will be provided.

### Electronic Device

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package. Briefly, the semiconductor package may include various devices or chips. A device or chip may include memory chips such as volatile memory (e.g., DRAM), non-volatile memory (e.g., ROM), and flash memory, and application processor chips such as central processors (e.g., CPU), graphics processors (e.g., GPUs), digital signal processors, encryption processors, microprocessors, microcontrollers, and logic chips such as analog-to-digital converters and application-specific ICs (ASICs).

In addition, the device or chip may include an active device and a passive device.

An active device refers to a device that actively uses a nonlinear part of signal characteristics. In addition, a passive device refers to a device that does not use a nonlinear signal characteristic even if both linear and nonlinear signal characteristics exist. For example, an active device may include a transistor, an IC semiconductor device, and the like, and a passive device may include a capacitor, a resistor, and an inductor. The passive device may increase a signal processing speed of a semiconductor chip, which is an active device, or perform a filtering function. In addition, the chip may be a wireless communication chip available for Wi-Fi or 5G communication.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In this case, the electronic device may be a smart phone, a personal digital assistant, a digital video camera, a digital still camera, a vehicle, a high-performance server, a network system, a computer, a monitor, a tablet, a laptop, a netbook, a television, a video game, a smart watch, an automotive, or the like. However, the embodiment is not limited thereto, and may be any other electronic device that processes data in addition to these.

### Circuit Board and Semiconductor Package

Hereinafter, a circuit board and a semiconductor package according to an embodiment will be described.

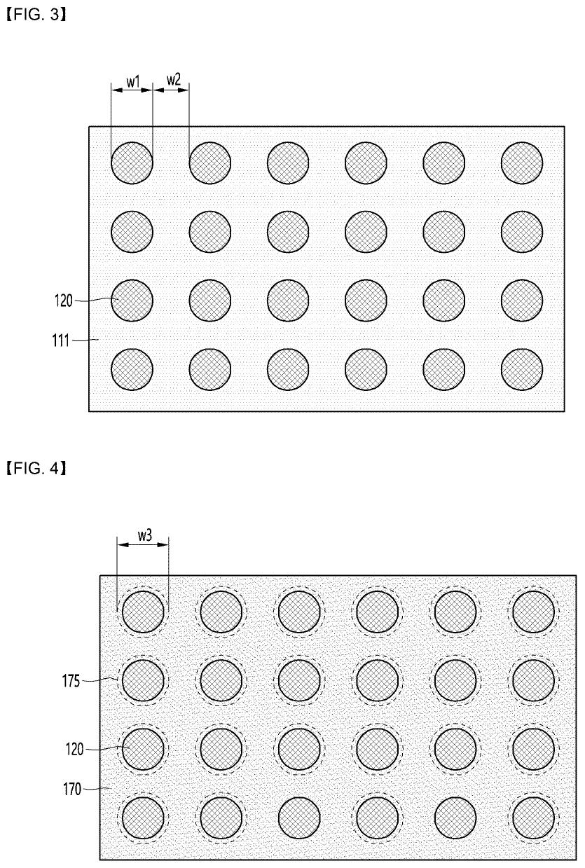

FIG. 2 is a cross-sectional view showing a circuit board according to the first embodiment. Hereinafter, an overall structure of the circuit board of a first embodiment will be described with reference to FIG. 2.

Referring to FIG. 2, the circuit board 100 allows at least one chip to be attached. In addition, the circuit board 100 of the embodiment enables attachment to a main board of an electronic device. The main board may mean a motherboard of an electronic device. The circuit board 100 may be connected to at least one chip and a motherboard to form a first package.

In addition, the first package including the circuit board 100 of the embodiment may be coupled with a second package. The second package may be a memory package. In one embodiment, the circuit board 100 may be coupled with a memory board of the second package. In another embodiment, the circuit board may be coupled with an interposer coupled to the memory board.

The circuit board 100 includes an insulating layer 110. The insulating layer 110 may include a plurality of layers. In one embodiment, the insulating layer 110 may have a three-layer structure, but is not limited thereto.

In one embodiment, the circuit board 100 may be a core board. For example, the circuit board 100 may include a core layer. For example, the insulating layer 110 of the circuit board 100 of the embodiment may include a third insulating layer 113 corresponding to the core layer including reinforcing fibers.

The circuit board 100 may have a structure in which at least one insulating layer is laminated on upper and lower portions of the third insulating layer 113 with the third insulating layer 113 interposed therebetween. In one embodiment, an insulating layer laminated on the upper portion of the third insulating layer 113 and an insulating layer laminated on the lower portion may have a symmetrical structure. In another embodiment, the insulating layer laminated on the upper portion of the third insulating layer 113 and the insulating layer laminated on the lower portion may have an asymmetrical structure.

Hereinafter, the circuit board 100 of the embodiment is described as a core board, and accordingly, the third insulating layer 113 is a core layer. However, the embodiment is not limited thereto. For example, the circuit board 100 of the other embodiment may be a coreless board that does not include a core layer.

Meanwhile, the circuit board of the embodiment has structural characteristics in the open structure of the protective layer. In addition, a protective layer and a circuit layer described below may be applied to the coreless board. Furthermore, at least one of circuit layers of outermost layers of the embodiment may have an ETS (Embedded Trace Substrate) structure embedded in a surface of the insulating layer 110.

The insulating layer 110 of the circuit board 100 of the embodiment may include a first insulating layer 111, a second insulating layer 112, and a third insulating layer 113.

The third insulating layer 113 may refer to an inner insulating layer disposed at an inner side of a plurality of insulating layers. The third insulating layer 113 may be disposed between the first insulating layer 111 and the second insulating layer 112. The third insulating layer 113 may include a prepreg. The third insulating layer 113 may include reinforcing fibers.

The first insulating layer 111 may be disposed on the third insulating layer 113. For example, the first insulating layer 111 may be disposed on an upper surface of the third insulating layer 113. The first insulating layer 111 may refer to a first outermost insulating layer of the insulating layer 110 of the circuit board 100. For example, the first insulating layer 111 may refer to an insulating layer disposed at an uppermost side among the insulating layer 110 of the circuit board 100. The first insulating layer 111 may provide a mounting region in which at least one chip is mounted, or a first bonding region to which a first external substrate is coupled. The first external substrate may be a main board of an electronic device.

The second insulating layer 112 may be disposed under the third insulating layer 113. The second insulating layer 112 may mean a second outermost insulating layer of the insulating layer 110 of the circuit board 100. For example, the second insulating layer 112 may mean an insulating layer disposed at a lowermost side among the insulating layer 110 of the circuit board 100. The second insulating layer 112 may provide a mounting region in which at least one chip is mounted, or a second bonding region to which a second external substrate is coupled. The second external substrate may be a memory substrate or an interposer.

The first insulating layer 111 and the second insulating layer 112 may be rigid or flexible. For example, the first insulating layer 111 and the second insulating layer 112 may include glass or plastic. In detail, the first insulating layer 111 and the second insulating layer 112 may include chemically strengthened/semi-strengthened glass such as soda lime glass or aluminosilicate glass. Alternatively, the first insulating layer 111 and the second insulating layer 112 may include a strengthened or flexible plastic such as polyimide (PI), polyethylene terephthalate (PET), propylene glycol (PPG), or polycarbonate (PC). Alternatively, the first insulating layer 111 and the second insulating layer 112 may include sapphire.

In addition, the first insulating layer 111 and the second insulating layer 112 may include an optically isotropic film. For example, the first insulating layer 111 and the second insulating layer 112 may include COC (Cyclic Olefin Copolymer), COP (Cyclic Olefin Polymer), optically isotropic polycarbonate (PC), or optically isotropic polymethylmethacrylate (PMMA).

In addition, the first insulating layer 111 and the second insulating layer 112 may be formed of a material including an inorganic filler and an insulating resin. For example, the first insulating layer 111 and the second insulating layer 112 may include a structure in which an inorganic filler such as silica or alumina is dispersed in a thermosetting resin such as an epoxy resin or a thermoplastic resin such as a polyimide. For example, the first insulating layer 111 and the second insulating layer 112 may include ABF (Ajinomoto Build-up Film), FR-4, BT (Bismaleimide Triazine), PID (Photo Imageable Dielectric resin), BT, etc.

Each of the first insulating layer 111 and the second insulating layer 112 may have a thickness in a range of 10 μm to 60 μm. Preferably, each of the first insulating layer 111 and the second insulating layer 112 may have a thickness in a range of 12 μm to 50 μm. More preferably, each of the first insulating layer 111 and the second insulating layer 112 may have a thickness in a range of 15 μm to 40 μm.

If the thickness of the first insulating layer 111 or the second insulating layer 112 is smaller than 10 μm, a circuit layer included in the circuit board 100 may not be stably protected. In addition, if the thickness of the first insulating layer 111 or the second insulating layer 112 exceeds 60 μm, a thickness of the circuit board 100 may increase, and thereby a thickness of the semiconductor package may increase. In addition, if the thickness of the first insulating layer 111 or the second insulating layer 112 exceeds 60 μm, a thickness of the circuit layer and a thickness of the through electrode may increase correspondingly. In addition, if the thickness of the circuit layer and the thickness of the through electrode increase, it may be difficult to implement miniaturization, and thus the circuit integration may decrease. In addition, a signal transmission distance may increase, and thus the signal transmission loss may increase.

The circuit board 100 of the embodiment includes a circuit layer disposed on a surface of an insulating layer 110.

For example, the circuit board 100 may include a first circuit layer 120 disposed on an upper surface of a first insulating layer 111. For example, the circuit board 100 may include a second circuit layer 130 disposed on a lower surface of a second insulating layer 112. In addition, the circuit board 100 may include a third circuit layer 140 disposed between a lower surface of the first insulating layer 111 and an upper surface of a third insulating layer 113. For example, the circuit board 100 may include a fourth circuit layer 150 disposed between a upper surface of the second insulating layer 112 and a lower surface of the third insulating layer 113.

The first circuit layer 120, the second circuit layer 130, the third circuit layer 140, and the fourth circuit layer 150 can be manufactured using conventional printed circuit board manufacturing processes such as an additive process, a subtractive process, a MSAP (Modified Semi Additive Process), and a SAP (Semi Additive Process), and a detailed description thereof is omitted here.

The first circuit layer 120 may refer to a circuit layer disposed at a first outermost layer of the circuit board 100. In addition, the second circuit layer 130 may refer to a circuit layer disposed at a second outermost layer of the circuit board 100.

The first circuit layer 120 may include a plurality of pads disposed on the first insulating layer 111.

In this case, the first circuit layer 120 in one embodiment may include only pads connected to the main board. However, the embodiment is not limited thereto. For example, the first circuit layer 120 may include a first pad connected to the main board and a second pad connected to a semiconductor device. In addition, the first pad and the second pad in the first circuit layer 120 may have different widths. Hereinafter, the first circuit layer 120 will be described based on a pad connected to the main board.

A pad of the first circuit layer 120 may be connected to the main board. Therefore, the pad of the first circuit layer 120 may have a width corresponding to an electrode provided in the main board. For example, a width of the pad of the first circuit layer 120 may be 70 μm or more. For example, the width of the pad of the first circuit layer 120 may be 80 μm or more. For example, the width of the pad of the first circuit layer 120 may be 90 μm or more. For example, the width of the pad of the first circuit layer 120 may be 100 μm or more.

Meanwhile, a pad of the second circuit layer 120 may have a smaller width than the pad of the first circuit layer 120. For example, a width of the pad of the second circuit layer 120 may be 25 μm to 65 μm. Preferably, the width of the pad of the second circuit layer 120 may be 30 μm to 60 μm. More preferably, the width of the pad of the second circuit layer 120 may be 32 μm to 55 μm.

If the width of the pad of the second circuit layer 120 is less than 25 μm, the bonding strength with the semiconductor device may be reduced. If the width of the second circuit layer 120 is less than 25 μm, the characteristics of the semiconductor device mounted on the circuit board may be reduced. If the width of the pad of the second circuit layer 120 exceeds 65 μm, it may be difficult to dispose all the pads connected to the semiconductor device within a limited space. For example, if the width of the pad of the second circuit layer 120 exceeds 65 μm, the circuit integration may be reduced.

Meanwhile, the width of the pad of the first circuit layer 120 may be greater than the width of the pad of the second circuit layer 120. Preferably, the width of the pad of the first circuit layer 120 may correspond to the width of the electrode provided in the main board, but is not limited thereto. This will be described in more detail below.

Meanwhile, the first circuit layer 120, the second circuit layer 130, the third circuit layer 140, and the fourth circuit layer 150 may be formed of at least one metal material selected from gold (Au), silver (Ag), platinum (Pt), titanium (Ti), tin (Sn), copper (Cu), and zinc (Zn). In addition, the first circuit layer 120, the second circuit layer 130, the third circuit layer 140, and the fourth circuit layer 150 may be formed of a paste or solder paste including at least one metal material selected from gold (Au), silver (Ag), platinum (Pt), titanium (Ti), tin (Sn), copper (Cu), and zinc (Zn) having excellent bonding strength. Preferably, the first circuit layer 120, the second circuit layer 130, the third circuit layer 140, and the fourth circuit layer 150 may be formed of copper (Cu) which is relatively inexpensive.

Meanwhile, the first circuit layer 120 and the second circuit layer 130 may have a thickness in a range of 5 μm to 30 μm. For example, the first circuit layer 120 and the second circuit layer 130 may have a thickness in a range of 6 μm to 25 μm. The first circuit layer 120 and the second circuit layer 130 may have a thickness in a range of 7 μm to 20 μm. If the thickness of the first circuit layer 120 and the second circuit layer 130 is smaller than 5 μm, resistance may increase and signal transmission loss may increase. If the thickness of the first circuit layer 120 and the second circuit layer 130 exceeds 30 μm, it is difficult to miniaturize, and accordingly, circuit integration may be reduced.

The circuit board 100 of the embodiment may include a through electrode. The through electrode may penetrate the insulating layer 110.

For example, the circuit board 100 may include a first through electrode 161 penetrating the first insulating layer 111. In addition, the circuit board 100 may include a second through electrode 162 penetrating the second insulating layer 112. In addition, the circuit board 100 may include a third through electrode 163 penetrating the third insulating layer 113.

The first through electrode 161, the second through electrode 162, and the third through electrode 163 may be disposed in a through hole penetrating at least one insulating layer. For example, the first through electrode 161, the second through electrode 162, and the third through electrode 163 may be formed by filling the through hole with a conductive material.

The through hole may be formed by any one of mechanical, laser, and chemical processing methods. The through hole may be formed by mechanical processing methods such as milling, drilling, and routing. In addition, the through hole may use a UV or CO₂ laser method. In addition, the through hole may use a chemical processing method using a chemical agent including minosilane, ketones, etc.

Meanwhile, the circuit board 100 of the embodiment includes a protective layer.

Specifically, a first protective layer 170 may be disposed on the first insulating layer 111.

The first protective layer 170 may include an opening 175.

The opening 175 of the first protective layer 170 may be defined as a recess portion. For example, the opening 175 of the first protective layer 170 may be non-penetrating to the first protective layer 170. Preferably, the first protective layer 170 may include an upper surface and a lower surface. In addition, a bottom surface of the opening 175 of the first protective layer 170 may be positioned higher than the lower surface of the first protective layer 170. For example, the opening 175 of the first protective layer 170 may also be referred to as a recess portion that is concave from the upper surface to the lower surface of the first protective layer 170.

The opening 175 of the first protective layer 170 may be vertically overlapped with the first circuit layer 120. Preferably, the opening 175 of the first protective layer 170 may vertically overlap with the pad of the first circuit layer 120. At this time, the opening 175 of the first protective layer 170 may have a width greater than that of the pad of the first circuit layer 120. Accordingly, an upper surface of the pad of the first circuit layer 120 may not be covered by the first protective layer 170.

Furthermore, the bottom surface of the opening 175 of the first protective layer 170 may be positioned lower than the upper surface of the pad of the first circuit layer 120 and higher than the lower surface of the pad of the first circuit layer 120.

Therefore, at least a portion of the pad of the first circuit layer 120 may horizontally overlap with the opening 175 of the first protective layer 170. Accordingly, a side surface of the pad of the first circuit layer 120 may include a first portion covered with the first protective layer 170. In addition, the side surface of the pad of the first protective layer 170 may include a second portion that is horizontally overlapped with the opening 175 of the first protective layer 170 and is not covered with the first protective layer 170.

Meanwhile, the circuit board 100 may further include a second protective layer 180 disposed on a lower surface of the second insulating layer 112.

The second protective layer 180 may include at least one opening 185. For example, the second protective layer 180 may include an opening 185 vertically overlapped with at least a portion of the second circuit layer 130. The opening of the second protective layer 180 may completely or partially vertically overlap with a pad connected to a chip among the second circuit layers 130.

For example, the opening 185 of the second protective layer 180 may have a SMD type. Specifically, the opening 185 of the second protective layer 180 may be provided with a different type from the opening 175 of the first protective layer 170.

Hereinafter, a structure of the opening 175 of the first protective layer 170 will be described.

Meanwhile, the first protective layer 170 and the second protective layer 180 may include an insulating material. The first protective layer 170 and the second protective layer 180 may include various materials that can be applied and then cured by heating to protect surfaces of the insulating layer and the circuit layer.

The first protective layer 170 and the second protective layer 180 may be solder resist layers including an organic polymer material. For example, the first protective layer 170 and the second protective layer 180 may include an epoxy acrylate series resin. In detail, the first protective layer 170 and the second protective layer 180 may include a resin, a curing agent, a photo initiator, a pigment, a solvent, a filler, an additive, an acrylic monomer, etc. However, the embodiment is not limited thereto, and the first protective layer 170 and the second protective layer 180 may be any one of a photo solder resist layer, a cover-lay, and a polymer material.

A thickness of the first protective layer 170 and the second protective layer 180 may be 1 μm to 20 μm. The thickness of the first protective layer 170 and the second protective layer 180 may be 1 μm to 15 μm. For example, the thickness of the first protective layer 170 and the second protective layer 180 may be 5 μm to 20 μm. If the thickness of the first protective layer 170 and the second protective layer 180 exceeds 20 μm, the overall thickness of the circuit board and the semiconductor package may increase.

At this time, the thickness of the first protective layer 170 and the thickness of the second protective layer 180 may mean a thickness of a protruding portion of a corresponding protective layer from a surface of a reference circuit layer.

For example, a thickness of the first protective layer 170 may mean a vertical distance from an upper surface of the first circuit layer 120 to an upper surface of the first protective layer 170. For example, a thickness of the second protective layer 180 may mean a vertical distance from a lower surface of the second circuit layer 120 to a lower surface of the second protective layer 180.

Meanwhile, a surface treatment layer may be disposed on the pad of the first circuit layer 120 exposed through the opening 175 of the first protective layer 170. The surface treatment layer may be an OSP (Organic Solderability Preservative) layer. For example, the surface treatment layer may be an organic coating layer coated with an organic material such as benzimidazole. However, the embodiment is not limited thereto. For example, the surface treatment layer may be a plating layer. For example, the surface treatment layer may include at least one of a nickel (Ni) plating layer, a palladium (Pd) plating layer, and a gold (Au) plating layer.

Hereinafter, a part of the configuration of the circuit board 100 illustrated in FIG. 2 will be specifically described.

FIG. 3 is a plan view of a circuit board in a state in which the first protective layer of FIG. 2 is removed, FIG. 4 is a plan view of the circuit board of FIG. 2, and FIG. 5 is an enlarged view showing a partial region of FIG. 2.

Referring to FIG. 3, a first circuit layer 120 may be disposed on the first insulating layer 111. For example, the first circuit layer 120 including a plurality of pads may be disposed on the first insulating layer 111.

A width W1 of the pads of the first circuit layer 120 may be 70 μm or more, 80 μm or more, 90 μm or more, or 100 μm or more.

For example, a width W1 of the pads of the first circuit layer 120 may satisfy a range of 70 μm to 150 μm. For example, the width W1 of the pads of the first circuit layer 120 may satisfy a range of 75 μm to 145 μm. For example, the width W1 of the pads of the first circuit layer 120 may satisfy a range of 80 μm to 140 μm.

If the width W1 of the pads of the first circuit layer 120 is smaller than 70 μm, a contact area between the pad and the connecting member may decrease. In addition, when the contact area is reduced, a physical and/or electrical reliability problem may occur in which the connection member is separated from the pad. In addition, when the contact area is reduced, the bonding strength between the circuit board and the main board may be reduced. In addition, if the width W1 of the pads of the first circuit layer 120 is smaller than 70 μm, a difference in the width between the pad and the electrode of the main board may be increased. In addition, when the difference in width is increased, the physical characteristics and/or electrical characteristics therebetween may be deteriorated. For example, when the difference in width is increased, the transmission loss of the electrical signal transmitted through the pads of the first circuit layer 120 may increase.

Meanwhile, if the width W1 of the pads of the first circuit layer 120 exceeds 150 μm, an overall planar area of the circuit board may increase accordingly.

Meanwhile, the pads of the first circuit layer 120 may have a circular planar shape. In addition, when the planar shape of the pads of the first circuit layer 120 is circular, the width W1 may mean a diameter of the pads of the first circuit layer 120.

In another embodiment, the planar shape of the pads of the first circuit layer 120 may be square or rectangular. In addition, when the planar shape of the pads of the first circuit layer 120 is square or rectangular, the width W1 may mean a smaller width among a width of the pads of the first circuit layer 120 in a width direction and a width in a length direction.

In another embodiment, the planar shape of the pads of the first circuit layer 120 may be elliptical. In addition, when the planar shape of the pads of the first circuit layer 120 is elliptical, the width W1 may mean a diameter in a short axis direction of the pad having the elliptical shape.

Meanwhile, the plurality of pads of the first circuit layer 120 may be spaced apart at a certain spacing W2. The spacing W2 may mean a separation distance between most adjacent pads among the plurality of pads.

The spacing W2 between the plurality of pads of the first circuit layer 120 may have a range corresponding to the width W1 of the pads of the first circuit layer 120.

In another embodiment, the spacing W2 may be smaller than the width W1 of the pads of the first circuit layer 120.

For example, the spacing W2 between the plurality of pads of the first circuit layer 120 may satisfy a range of 20% to 90% of the width W1 of the pads. Preferably, the spacing W2 between the plurality of pads of the first circuit layer 120 can satisfy a range of 23% to 88% of the width W1 of the pads. More preferably, the spacing W2 between the plurality of pads of the first circuit layer 120 can satisfy a range of 25% to 85% of the width W1 of the pads.

If the spacing W2 between the plurality of pads of the first circuit layer 120 is less than 20% of the width of the pads, a circuit short may occur in which the plurality of pads are connected to each other depending on a process capability in a process of manufacturing the circuit board 100, thereby deteriorating the electrical reliability of the circuit board 100. In addition, if the spacing W2 between the plurality of pads of the first circuit layer 120 is less than 20% of the width W1 of the pads, interference may occur between signals transmitted through the plurality of pads. In addition, when interference occurs, signal transmission loss increases, and thus, signal transmission characteristics may deteriorate.

Meanwhile, if the spacing W2 between the plurality of pads of the first circuit layer 120 exceeds 90% of the width W1 of the pads, it may be difficult to dispose all the pads connected to the main board within a limited space.

Meanwhile, referring to FIG. 4, the first protective layer 170 may be disposed entirely on the first insulating layer 111. For example, the first protective layer 170 may be disposed to entirely cover an upper surface of the first insulating layer 111.

Furthermore, the first protective layer 170 may include an opening 175. The opening 175 of the first protective layer 170 may vertically overlap with the pads of the first circuit layer 120. For example, the opening 175 of the first protective layer 170 may include a region having a width greater than the width W1 of the pad of the first circuit layer 120. At this time, the opening 175 of the first protective layer 170 of the circuit board of the first embodiment may not have a step. Therefore, the opening 175 of the first protective layer 170 in the first embodiment may have a width greater than the width W1 of the pad of the first circuit layer 120 in an entire region.

Therefore, an upper surface of the pad of the first circuit layer 120 may not contact the first protective layer 170. Preferably, the pad of the first circuit layer 120 may vertically overlap with the opening 175 of the first protective layer 170 as a whole.

Accordingly, the embodiment may improve a contact area between the pad and the connecting member disposed on the pad of the first circuit layer 120. That is, in the comparative example, the width of the opening was smaller than the width of the pad, and accordingly, the contact area between the pad and the connecting member was smaller than the planar area of the pad.

In contrast, the contact area between the pad and the connecting member in the circuit board of the first embodiment is greater than the planar area of the pad. Therefore, the embodiment can improve the bonding strength between the pad and the connecting member. Accordingly, the embodiment can solve the physical and/or electrical reliability problem of the connecting member being separated from the pad. Therefore, the embodiment can improve the product characteristics of the circuit board. Furthermore, the embodiment can improve the bonding strength with the main board coupled on the circuit board.

Meanwhile, a width W3 of the opening 175 of the first protective layer 170 can satisfy a range of 105% to 150% of the width W1 of the pad of the first circuit layer 120. The width W3 of the opening 175 of the first protective layer 170 can satisfy a range of 110% to 145% of the width W1 of the pad of the first circuit layer 120. The width W3 of the opening 175 of the first protective layer 170 can satisfy a range of 115% to 140% of the width W1 of the pad of the first circuit layer 120.

If the width W3 of the opening 175 of the first protective layer 170 is less than 105% of the width W1 of the pad of the first circuit layer 120, an effect of increasing the contact area between the pad and the connecting member may be insignificant.

In addition, if the width W3 of the opening 175 of the first protective layer 170 exceeds 150% of the width W1 of the pad of the first circuit layer 120, a circuit short problem may occur in which the connecting members disposed on neighboring pads are electrically connected to each other.

Preferably, the width W3 of the opening 175 of the first protective layer 170 may be determined based on the spacing W2 between the plurality of pads of the first circuit layer 120.

Referring to FIG. 5, the pad of the first circuit layer 120 may be disposed on the first insulating layer 111.

At this time, the first circuit layer 120 may be composed of at least two metal layers. In addition, the first through electrode 161 may include two metal layers corresponding to the first circuit layer 120.

That is, the pad of the first circuit layer 120 may include a first metal layer 120-1 and a second metal layer 120-2.

Furthermore, the first through electrode 161 may include a third metal layer 161-1 corresponding to the first metal layer 120-1 of the first circuit layer 120 and a fourth metal layer 161-2 corresponding to the second metal layer 120-2.

At this time, the first metal layer 120-1 and the third metal layer 161-1 may substantially mean one layer, and may be distinguished according to an arrangement position. In addition, the second metal layer 120-2 and the fourth metal layer 161-2 may also substantially mean one metal layer, and may be distinguished according to the arrangement position.

In addition, the first metal layer 120-1 may be substantially two layers. The first metal layer 120-1 may be two metal layers including a same metal layer as the third metal layer 161-1 on copper foil (Cu foil).

In addition, the first metal layer 120-1 may be one layer of copper foil (Cu foil).

Accordingly, only the first metal layer 120-1 and the second metal layer 120-2 will be described below.

The first metal layer 120-1 of the first circuit layer 120 may be a seed layer. The first metal layer 120-1 of the first circuit layer 120 may be a chemical copper plating layer. The first metal layer 120-1 of the first circuit layer 120 may be a copper foil layer. The first metal layer 120-1 of the first circuit layer 120 may include both a copper foil layer and a chemical copper plating layer.

A thickness of the first metal layer 120-1 of the first circuit layer 120 may satisfy a range of 1.0 μm to 3.0 μm. Preferably, the thickness of the first metal layer 120-1 of the first circuit layer 120 may satisfy a range of 1.2 μm to 2.8 μm. More preferably, the thickness of the first metal layer 120-1 of the first circuit layer 120 may satisfy a range of 1.5 μm to 2.5 μm.

If the thickness of the first metal layer 120-1 of the first circuit layer 120 is less than 1.0 μm, the first metal layer 120-1 of the first circuit layer 120 may not function as a seed layer. If the thickness of the first metal layer 120-1 of the first circuit layer 120 is less than 1.0 μm, it may be difficult to form a first metal layer 120-1 with a uniform thickness on an upper surface of the first insulating layer 110.

If the thickness of the first metal layer 120-1 of the first circuit layer 120 exceeds 3.0 μm, a process time for forming the first metal layer 120-1 of the first circuit layer 120 may increase, and the yield may decrease accordingly. In addition, if the thickness of the first metal layer 120-1 of the first circuit layer 120 exceeds 3.0 μm, an etching time of the first metal layer 120-1 in a process of forming the first circuit layer 120 may increase. In addition, if the thickness of the first metal layer 120-1 of the first circuit layer 120 exceeds 3.0 μm, deformation of the second metal layer 120-2 of the first circuit layer 120 may occur when the first metal layer 120-1 of the first circuit layer 120 is etched. Here, deformation of the second metal layer 120-2 of the first circuit pattern layer 120 may mean that a difference between the width of the upper surface and the width of the lower surface of the second metal layer 120-2 increases as the side of the second metal layer 120-2 is also etched when the first metal layer 120-1 is etched. In addition, if the thickness of the first metal layer 120-1 of the first circuit layer 120 exceeds 3.0 μm, an etching amount in an etching process of the first metal layer 120-1 increases, and accordingly, a depth of a groove (e.g., undercut) formed at a side portion of the first metal layer 120-1 and a side portion of the second metal layer 120-2 may increase. For example, when the etching amount in the etching process of the first metal layer 120-1 increases, a difference between the width of the first metal layer 120-1 and the width of the second metal layer 120-2 may increase. In addition, when the difference between the width of the first metal layer 120-1 and the width of the second metal layer 120-2 increases, electrical characteristics may deteriorate due to an increase in signal transmission loss. In addition, when the difference between the width of the first metal layer 120-1 and the width of the second metal layer 120-2 increases, dendrites may be formed by electromigration, thereby deteriorating the electrical characteristics and/or physical characteristics of the first circuit layer 120.

The second metal layer 120-2 of the first circuit layer 120 may be an electroplated layer electroplated using the first metal layer 120-1 as a seed layer. The second metal layer 120-2 of the first circuit layer 120 may be formed on the first metal layer 120-1 with a certain thickness. The second metal layer 120-2 of the first circuit layer 120 may include a same metal as the first metal layer 120-1 of the first circuit layer 120, but is not limited thereto. For example, the first metal layer 120-1 and the second metal layer 120-2 of the first circuit layer 120 may each include copper.

A thickness of the second metal layer 120-2 of the first circuit layer 120 may correspond to a value obtained by subtracting the thickness of the first metal layer 120-1 from a thickness range of the first circuit layer 120. In addition, since the thickness range of the first circuit layer 120 has already been described above, a description thereof will be omitted. That is, the thickness T1 of the first circuit layer 120 may satisfy a range of 5 μm to 30 μm. For example, the thickness T1 of the first circuit layer 120 may satisfy a range of 6 μm to 25 μm. The thickness T1 of the first circuit layer 120 may satisfy a range of 7 μm to 20 μm.

Meanwhile, a first protective layer 170 may be disposed on the first insulating layer 111. In addition, the first protective layer 170 may include an opening 175 having a width greater than the width W1 of the pad of the first circuit layer 120. At this time, the first protective layer 170 may include a side wall 175S of the opening 175 and a bottom surface 175B of the opening 175.

At this time, the side wall 175S of the first protective layer 170 may be spaced apart from a side surface of the pad of the first circuit layer 120 by a predetermined spacing W4. At this time, a spacing between the side surface of the pad of the first circuit layer 120 and the side wall 175S of the opening 175 of the first protective layer 170 may be different along the circumferential direction of the side surface of the pad of the first circuit layer 120. In addition, the spacing W4 may mean a spacing at an farthest position along the circumferential direction.

The spacing W4 between the side surface of the pad of the first circuit layer 120 and the side wall 175S of the first protective layer 170 may be determined based on the spacing W2 between the plurality of pads of the first circuit layer 120. Preferably, the spacing W4 between the side surface of the pad of the first circuit layer 120 and the side wall 175S of the first protective layer 170 may satisfy a range of 5% to 45% of the spacing W2 between the plurality of pads of the first circuit layer 120. For example, the spacing W4 between the side surface of the pad of the first circuit layer 120 and the side wall 175S of the first protective layer 170 may satisfy a range of 8% to 40% of the spacing W2 between the plurality of pads of the first circuit layer 120. For example, the spacing W4 between the side surface of the pad of the first circuit layer 120 and the side wall 175S of the first protective layer 170 may satisfy a range of 10% to 35% of the spacing W2 between the plurality of pads of the first circuit layer 120.

If the spacing W4 between the side surface of the pad of the first circuit layer 120 and the side wall 175S of the first protective layer 170 is less than 5% of the spacing W2 between the plurality of pads of the first circuit layer 120, an effect of increasing the contact area between the pad and the connecting member in the embodiment may be minimal.

In addition, if the spacing W4 between the side surface of the pad of the first circuit layer 120 and the side wall 175S of the first protective layer 170 exceeds 45% of the spacing W2 between the plurality of pads of the first circuit layer 120, a circuit short problem may occur due to the connection members disposed on the neighboring pads being electrically connected to each other.

Meanwhile, the bottom surface 175B of the opening 175 of the first protective layer 170 may be positioned lower than the upper surface of the pad of an first circuit layer 120. In addition, the bottom surface 175B of the opening 175 of the first protective layer 170 may be positioned higher than the lower surface of the pad of the first circuit layer 120.

Accordingly, a part of the side surface of the pad of the first circuit layer 120 based on the bottom surface 175B of the opening 175 may be covered by the first protective layer 170, and a remaining part of the side surface of the pad of the first circuit layer 120 may not be covered by the first protective layer 170. Preferably, the remaining part of the side surface of the pad may horizontally overlap with the opening 175 of the first protective layer 170.

Meanwhile, a vertical distance T2 between the bottom surface 175B of the opening 175 of the first protective layer 170 and the lower surface of the first protective layer 170 can be determined based on the thickness T1 of the pad of the first circuit layer 120. For example, the vertical distance T2 between the bottom surface 175B of the opening 175 of the first protective layer 170 and the lower surface of the first protective layer 170 can satisfy a range of 20% to 90% of the thickness T1 of the pad of the first circuit layer 120. For example, the vertical distance T2 between the bottom surface 175B of the opening 175 of the first protective layer 170 and the lower surface of the first protective layer 170 can satisfy a range of 25% to 85% of the thickness T1 of the pad of the first circuit layer 120. For example, the vertical distance T2 between the bottom surface 175B of the opening 175 of the first protective layer 170 and the lower surface of the first protective layer 170 may satisfy a range of 30% to 80% of the thickness T1 of the pad of the first circuit layer 120.

For example, if the vertical distance T2 between the bottom surface 175B of the opening 175 of the first protective layer 170 and the lower surface of the first protective layer 170 is less than 20% of the thickness T1 of the pad of the first circuit layer 120, an area of the side surface of the pad of the first circuit layer 120 covered by the first protective layer 170 may decrease. As a result, the bonding strength between the pad of the first circuit layer 120 and the first insulating layer 111 may decrease. In addition, if the vertical distance T2 between the bottom surface 175B of the opening 175 of the first protective layer 170 and the lower surface of the first protective layer 170 exceeds 90% of the thickness T1 of the pad of the first circuit layer 120, a reliability problem may occur in which an upper surface of the pad of the first circuit layer 120 is covered with the first protective layer 170 due to a process error in a process of forming the opening 175.

As described above, the embodiment can improve the contact area between the pad and the connecting member disposed on the pad of the first circuit layer 120. That is, in the comparative example, the width of the opening was smaller than the width of the pad, and accordingly, the contact area between the pad and the connecting member was smaller than the planar area of the pad.

In contrast, the contact area between the pad and the connecting member in the circuit board of the first embodiment is greater than the planar area of the pad. Therefore, the embodiment can improve the bonding strength between the pad and the connecting member. Accordingly, the embodiment can solve the physical and/or electrical reliability problem of the connecting member being separated from the pad. Therefore, the embodiment can improve the product characteristics of the circuit board. Furthermore, the embodiment can improve the bonding strength with the main board coupled on the circuit board.

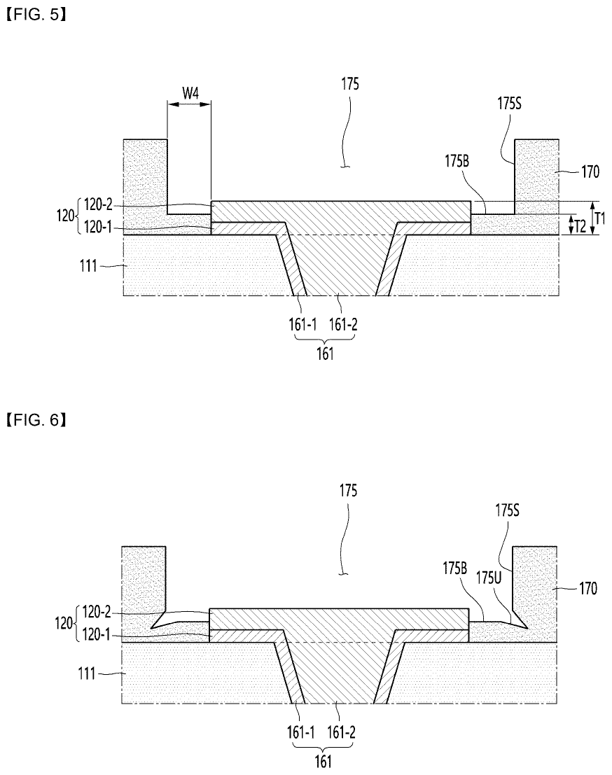

FIG. 6 is a drawing showing a first modified example of the circuit board of FIG. 5, and FIG. 7 is a drawing showing a second modified example of the circuit board of FIG. 5.

Referring to FIG. 6, the first protective layer 170 may include an opening 175, and may include a side wall 175S and a bottom surface 175B of the opening 175.

In addition, the first protective layer 170 may include a recess portion 175U provided between the side wall 175S and the bottom surface 175B.

At this time, the recess portion 175U may be provided concavely toward an inside of the first protective layer 170 between the side wall 175S and the bottom surface 175B. Furthermore, the embodiment can minimize a size of the recess portion 175U by controlling a height of the bottom surface 175B of the first protective layer 170. That is, the vertical distance T2 between the bottom surface 175B of the opening 175 of the first protective layer 170 and the lower surface of the first protective layer 170 can satisfy a range of 20% to 90%, a range of 25% to 85%, or a range of 30% to 80% of the thickness T1 of the pad of the first circuit layer 120. Through this, the embodiment can minimize a horizontal distance between the side wall 175S of the first protective layer 170 and an innermost surface of the recess portion 175U.

Meanwhile, referring to FIG. 7, the embodiment can form an opening 175 in the first protective layer 170 through a removal process for thinning a thickness. For example, the removal process for thinning the thickness can be referred to as a thinning process. In addition, since the opening 175 of the first protective layer 170 is formed through the removal process for thinning the thickness, the embodiment can easily adjust the height of the bottom surface 175B of the opening 175. For example, in a prior art, the opening was formed through an exposure and development process, and it was impossible to adjust the height of the bottom surface of the opening formed thereby. In contrast, the embodiment can easily adjust the height of the bottom surface 175B by forming the opening 175 by the removal process for thinning the thickness.

Therefore, the side wall of the opening 175 of the first protective layer 170 can have an incline. For example, the first protective layer 170 can include an inclined wall 175IS provided between the side wall 175S of the opening 175 and the bottom surface 175B and having a certain incline angle. At this time, the inclined wall 175IS can be closer to the pad of the first circuit layer 120 as it goes from the side wall 175S toward the bottom surface 175B. Therefore, the embodiment can improve the flowability of the connecting member in a process of arranging the connecting member, and can improve the bonding force between the pad and the connecting member accordingly.

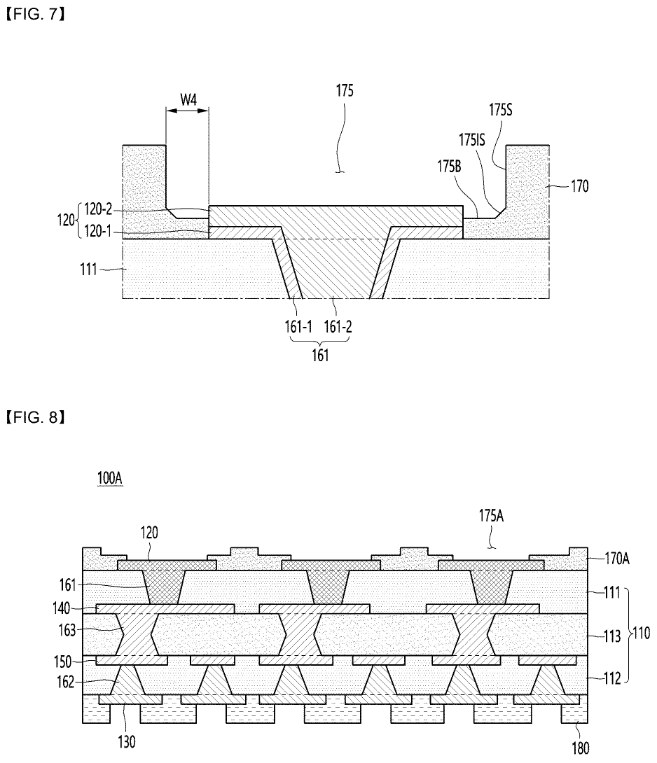

FIG. 8 is a cross-sectional view showing a circuit board according to a second embodiment, and FIG. 9 is an enlarged view showing a partial region of FIG. 8.

Referring to FIGS. 8 and 9, the circuit board of the second embodiment may be different from the circuit board of FIG. 2 in that the opening provided in the first protective layer has a step. Hereinafter, a description of a part that is substantially the same as the circuit board of FIG. 2 will be omitted.

The circuit board 100A of the second embodiment may include a first protective layer 170A disposed on a first insulating layer 111 and including an opening 175A.

The opening 175A of the first protective layer 170A may have a step. In this case, a fact that the opening 175A has a step may mean that the width of the opening 175A of the first protective layer 170A changes in a vertical direction.

For example, the opening 175A of the first protective layer 170A may be divided into a plurality of parts. In addition, at least some of the openings 175A of the first protective layer 170A may have a width greater than the width of the pad of the first circuit layer 120.

The opening 175A of the first protective layer 170A may include a first part 175A1 and a second part 175A2.

Specifically, the opening 175A of the first protective layer 170A may include a first part 175A1 adjacent to the upper surface of the first protective layer 170A. In addition, a width of the first part 175A1 of the first protective layer 170A may be greater than the width of the pad of the first circuit layer 120.

In addition, the opening 175A of the first protective layer 170A may include a second part 175A2 closer to the pad of the first circuit layer 120 than the first part 175A1. At this time, the second part 175A2 of the opening 175A of the first protective layer 170A may have a width smaller than the width of the pad of the first circuit layer 120.

Therefore, the first protective layer 170A may cover at least a portion of the upper surface of the pad of the first circuit layer 120. However, in the second embodiment, the opening 175A of the first protective layer 170A may have a step while covering a portion of an upper surface of the pad of the first circuit layer 120. Accordingly, the embodiment can improve the bonding strength between the pad of the first insulating layer 111 and the first circuit layer 120 as the first protective layer 170A covers a part of the pad. Furthermore, the embodiment can prevent the connecting member disposed on the pad from overflowing as the opening 175A of the first protective layer 170A has a step. Through this, the embodiment can solve the problem of a circuit short due to the connecting members disposed on adjacent pads being electrically connected to each other.

Meanwhile, the first protective layer 170A may include a first side wall 175A1S of the first part 175A1 of the opening 175A. In addition, the first protective layer 170A may include a second side wall 175A2S of the second part 175A2 of the opening 175A. In addition, the first protective layer 170A may include a step portion 175A1B connecting the first side wall 175A1S and the second side wall 175A2S. In addition, a height of the step portion 175A1B may be positioned higher than the upper surface of the pad. For example, a height T3 from the lower surface of the first protective layer 170A to the step portion 175A1B may be positioned higher than the upper surface of the pad. At this time, the height T3 from the lower surface of the first protective layer 170A to the step portion 175A1B can satisfy a range of 110% to 140%, or 112% to 135%, or 115% to 130% of the thickness T1 of the pad of the first circuit layer 120. The step portion 175A1B can also be referred to as a bottom surface of the first part 175A1 of the first opening 175A.

If the height T3 from the lower surface of the first protective layer 170A to the step portion 175A1B is less than 110% of the thickness T1 of the pad of the first circuit layer 120, a problem may occur in which the upper surface of the pad of the first circuit layer 120 is not covered by the first protective layer 170A due to a process error in the process of forming the opening 175A in the first protective layer 170A.

If the height T3 from the lower surface of the first protective layer 170A to the step portion 175A1B exceeds 140% of the thickness T1 of the pad of the first circuit layer 120, the degree of blocking of overflow of the connecting member disposed in the opening 175A may decrease, or an overall thickness of the first protective layer 170A may increase to improve the degree of blocking.

In addition, the embodiment may have a step in the opening of the protective layer. At this time, a connecting member such as solder is disposed in the opening of the protective layer. At this time, when the connecting member is disposed on the pad, a metal bonding layer may be formed between the connecting member and the pad. At this time, the embodiment may increase a length of the side wall of the opening between the upper surface of the first protective layer and the metal bonding layer by making the opening of the protective layer have a step. For example, in the comparative example, the side wall of the opening connecting the upper surface of the protective layer and the metal bonding layer (IMC) has a structure without an inflection point. Accordingly, in the comparative example, in order to increase the distance of the inner wall of the opening between the upper surface of the protective layer and the metal bonding layer (IMC), the thickness of the protective layer had to be increased.

In contrast, in the embodiment, by forming a step in the opening, the length of the side wall of the opening between the metal bonding layer (IMC) and the upper surface of the first protective layer can be increased without increasing a thickness of the first protective layer, thereby improving physical reliability of the metal bonding layer (IMC).

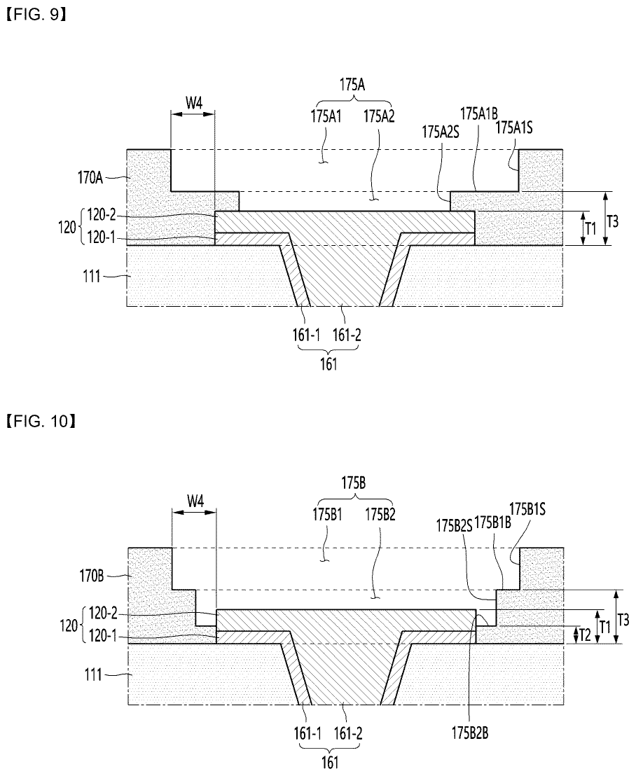

FIG. 10 is an enlarged view of a part of a circuit board according to a third embodiment.

Referring to FIG. 10, the circuit board of the third embodiment may be different from the circuit board of FIG. 2 in that the opening provided in the first protective layer has a step. Hereinafter, a description of a part that is substantially the same as the circuit board of FIG. 2 will be omitted.

The circuit board 100A of the third embodiment may include a first protective layer 170B disposed on the first insulating layer 111 and including an opening 175B.

The opening 175B of the first protective layer 170B may have a step. In this case, a fact that the opening 175B has a step may mean that the width of the opening 175B of the first protective layer 170B includes a region that changes in the vertical direction.

For example, the opening 175B of the first protective layer 170B may be divided into a plurality of parts. In addition, at least some of the openings 175B of the first protective layer 170B may have a width greater than the width of the pad of the first circuit layer 120.

The opening 175B of the first protective layer 170B may include a first part 175B1 and a second part 175B2.

Specifically, the opening 175B of the first protective layer 170B may include a first part 175B1 adjacent to the upper surface of the first protective layer 170B. In addition, a width of the first part 175B1 of the first protective layer 170B may be greater than the width of the pad of the first circuit layer 120.

In addition, the opening 175B of the first protective layer 170B may include a second part 175B2 adjacent to the pad of the first circuit layer 120 more than the first part 175B1. At this time, the second part 175B2 of the opening 175B of the first protective layer 170B may have a width greater than the width of the pad of the first circuit layer 120.

Therefore, the first protective layer 170B may entirely open the upper surface of the pad of the first circuit layer 120.

Meanwhile, the first protective layer 170B may include a first sidewall 175B1S of the first part 175B1 of the opening 175B. In addition, the first protective layer 170B may include a second side wall 175B2S of the second part 175B2 of the opening 175B. In addition, the first protective layer 170B may include a first bottom surface 175B1B of the first part 175B1 of the opening 175B connected to the first side wall 175B1S. In addition, the first bottom surface 175B1B may be positioned higher than the upper surface of the pad of the first circuit layer 120.

In addition, the first protective layer 170B may include a second bottom surface 175B2B of the second part 175B2 of the opening 175B connected to the second side wall 175B2S. In addition, the second bottom surface 175B2B may be positioned lower than the upper surface of the pad of the first circuit layer 120 and higher than the lower surface of the pad.

FIG. 11 is an enlarged view of a portion of a circuit board according to a fourth embodiment.

Referring to FIG. 11, the circuit board of the fourth embodiment may be different from the circuit board of FIG. 2 in that the opening provided in the first protective layer has a step. Hereinafter, a description of a part that is substantially the same as the circuit board of FIG. 2 will be omitted.

A circuit board 100A of the fourth embodiment may include a first protective layer 170C disposed on the first insulating layer 111 and including an opening 175B.

The opening 175C of the first protective layer 170C may have a step. At this time, the fact that the opening 175C has a step may mean that the width of the opening 175C of the first protective layer 170C includes a region in which the width changes in the vertical direction.

For example, the opening 175C of the first protective layer 170C may be divided into a plurality of parts. In addition, at least some of the openings 175C of the first protective layer 170C may have a width greater than the width of the pad of the first circuit layer 120.

At this time, the first protective layer 170C may be composed of a plurality of layers. For example, the first protective layer 170C may include a first layer 170C1 and a second layer 170C2. In addition, the opening 175C may be provided with a step in the first layer 170C1 and the second layer 170C2 of the first protective layer 170C.

The opening 175C of the first protective layer 170C may include a first part 175C1 and a second part 175C2.

Specifically, the opening 175C of the first protective layer 170C may include a first part 175C1 adjacent to the upper surface of the first protective layer 170C. Specifically, the opening 175C of the first protective layer 170C may include a first part 175C1 provided in the second layer 170C2 of the first protective layer 170C.

In addition, the width of the first part 175C1 of the first protective layer 170C may be greater than the width of the pad of the first circuit layer 120.

In addition, the opening 175C of the first protective layer 170C may include a second part 175C2 provided in the first layer 170C1. At this time, the second part 175C2 of the opening 175C provided in the first layer 170C1 of the first protective layer 170B may have a width greater than the width of the pad of the first circuit layer 120.

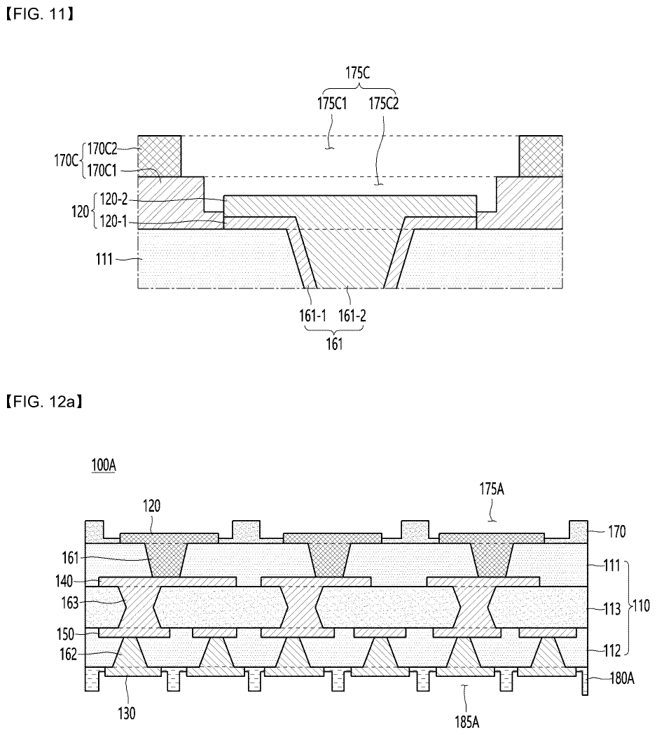

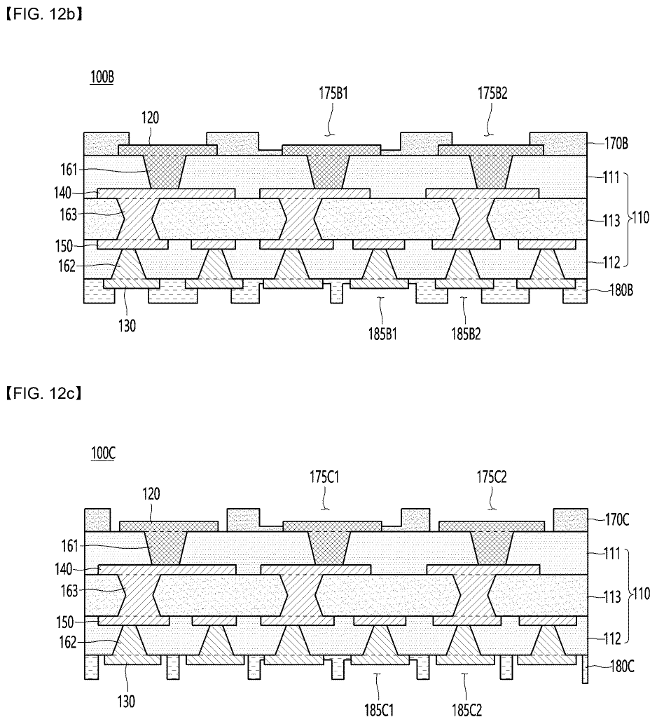

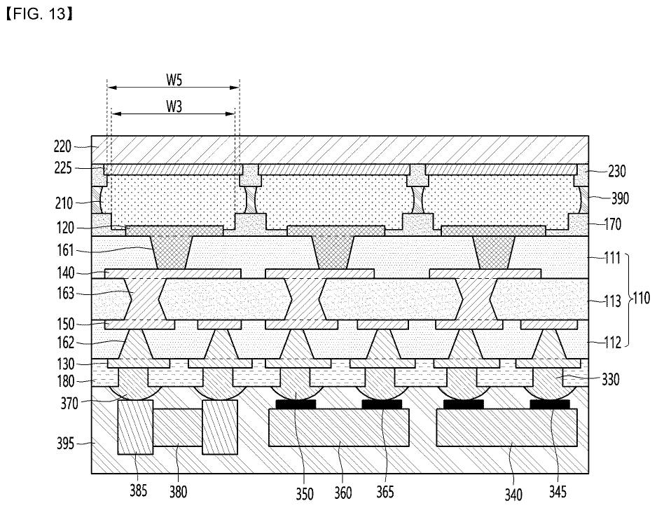

FIG. 12a is a cross-sectional view showing a circuit board according to a fifth embodiment, FIG. 12b is a cross-sectional view showing a circuit board according to a sixth embodiment, and FIG. 12c is a cross-sectional view showing a circuit board according to a seventh embodiment.

Referring to FIG. 12a, the circuit board 100A of the fifth embodiment may have a difference in the opening provided in the second protective layer compared to the circuit board of FIG. 2.

For example, the opening 185 provided in the second protective layer 180 of the first embodiment has a width smaller than the width of the second circuit layer 130. That is, the opening 185 provided in the second protective layer 180 of the first embodiment was provided as an SMD type.

The circuit board 100A of the fifth embodiment may have a shape corresponding to the opening 175 provided in the first protective layer 170.

Specifically, the circuit board 100A may include a second protective layer 180A. The second protective layer 180A may include an opening 185A. The opening 185A may have a width greater than the width of the pad of the third circuit layer 130.

At this time, the opening 185A of the second protective layer 180A may have a width greater than the pad of the third circuit layer 130 and may surround at least a portion of a side surface of the third circuit layer 130. For example, the second protective layer 180A may be in direct contact with at least a portion of the side surface of the third circuit layer 130. In addition, the second protective layer 180A may include an opening 185A that does not contact the remaining portion of the side surface of the third circuit layer 130. The opening 185A may overlap horizontally with the remaining portion of the side surface of the third circuit layer 130 and vertically overlap with the lower surface of the third circuit layer 130.

Referring to FIG. 12b, the protective layer of the sixth embodiment may have a structure in which multiple openings of different types are combined.

For example, the circuit board 100B of the sixth embodiment may include a first protective layer 170B. The first protective layer 170B may include an opening. At this time, the opening of the first protective layer 170B may include a plurality of openings of different types.

For example, the first protective layer 170B may include a first opening 175B1 and a second opening 175B2. The first opening 175B1 may correspond to the opening 175 described in the first embodiment. The second opening 175B2 may have a different type from the first opening 175B1. For example, the second opening 175B2 may have a width smaller than the width of the pad of the first circuit layer 120. That is, the second opening 175B2 may have an SMD type.

At this time, the opening of the first protective layer 170B may have a structure in which different types of first openings 175B1 and second openings 175B2 are combined.

The first opening 175B1 and the second opening 175B2 may be provided at different locations on the circuit board. Preferably, the first opening 175B1 may be provided in an inner region of the first protective layer 170B. In addition, the second opening 175B2 may be provided in an outer region adjacent to the side surface of the first protective layer 170B.

That is, the embodiment provides the second opening 175B2 in an outer region or edge region adjacent to the side surface of the first protective layer 170B, and the first opening 175B1 in the inner region. Through this, the embodiment can solve a warpage problem occurring on an outer side of the circuit board. For example, the embodiment allows the width of the second opening 175B2 provided in the outer region of the first protective layer 170B to be smaller than the width of the first opening 175B1 provided in the inner region. Accordingly, an area of the first protective layer 170B in the outer region may be greater than an area of the inner region of the first protective layer 170B. Through this, the embodiment can solve the warpage problem occurring in the circuit board.

For example, the second opening 175B2 may be provided as an SMD type depending on a direction of the warpage occurring in the circuit board. For example, when the circuit board is warped in a first vertical direction, the second opening 175B2 may have an SMD type.

Furthermore, the second protective layer 180B may also include the first opening 185B1 and the second opening 185B2. The first opening 185B1 of the second protective layer 180B may be of a type corresponding to the first opening 175B1 of the first protective layer 170B. In addition, the second opening 185B2 of the second protective layer 180B may be of a type corresponding to the second opening 175B2 of the first protective layer 170B.

Meanwhile, referring to FIG. 12C, the circuit board 100C of a seventh embodiment may include a first protective layer 170C. The first protective layer 170C may include an opening. At this time, the opening of the first protective layer 170C may include a plurality of openings of different types.

For example, the first protective layer 170C may include a first opening 175C1 and a second opening 175C2. The first opening 175C1 may correspond to the opening 175 described in the first embodiment. The second opening 175C2 may have a different type from the first opening 175C1. For example, the second opening 175C2 may have a width greater than the width of the pad of the first circuit layer 120. The second opening 175C2 may not contact the pad of the first circuit layer 120. That is, the second opening 175C2 may have an NSMD type.

At this time, the opening of the first protective layer 170C may have a structure in which the first opening 175C1 and the second opening 175C2 of different types are combined.

That is, depending on a direction of warpage occurring in the circuit board, the second opening 175B2 may be provided as an NSMD type.

For example, when the circuit board is bent in a second vertical direction opposite to the first vertical direction, the second opening 175C2 provided in the first protective layer 170C may have an NSMD type instead of an SMD type.

In addition, the second protective layer 180C may also include a first opening 185C1 and a second opening 185C2. The first opening 185C1 of the second protective layer 180C may be of a type corresponding to the first opening 175C1 of the first protective layer 170C. In addition, the second opening 185C2 of the second protective layer 180C may be of a type corresponding to the second opening 175C2 of the first protective layer 170C.

Meanwhile, the opening provided in the first protective layer may further include an SMD type opening and an NSMD type opening in addition to the openings of FIG. 2. For example, the first protective layer may further include the second opening 175C2 illustrated in FIG. 12c in addition to the first opening 175B1 and the second opening 175B2 illustrated in FIG. 12b.

In addition, the openings provided in the second protective layer may further include the second opening 185C2 illustrated in FIG. 12c in addition to the first opening 185B1 and the second opening 185B2 illustrated in FIG. 12b.

Meanwhile, the first protective layer and the second protective layer of the embodiment may have openings by combinations of different embodiments among the embodiments described above. For example, the first protective layer may include the opening of the circuit board of the first embodiment, and the second protective layer may include the opening of the fifth embodiment.

Hereinafter, a semiconductor package according to the embodiment will be described.

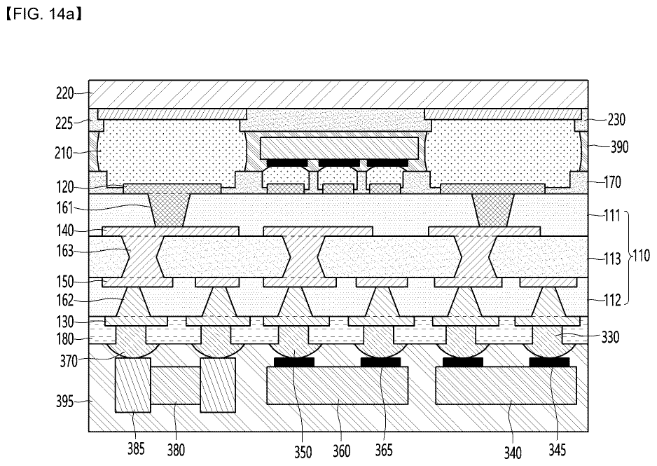

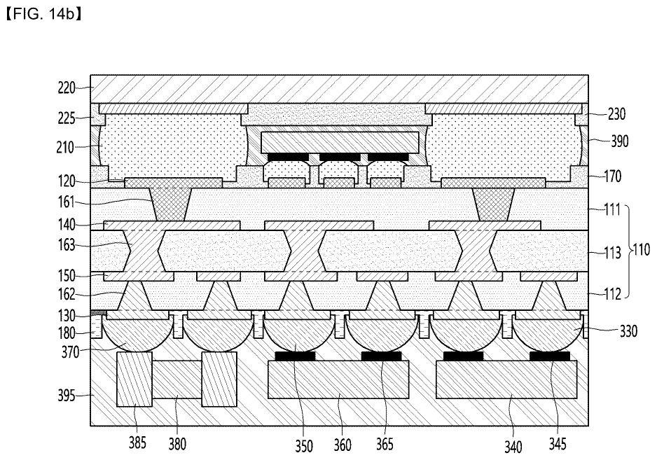

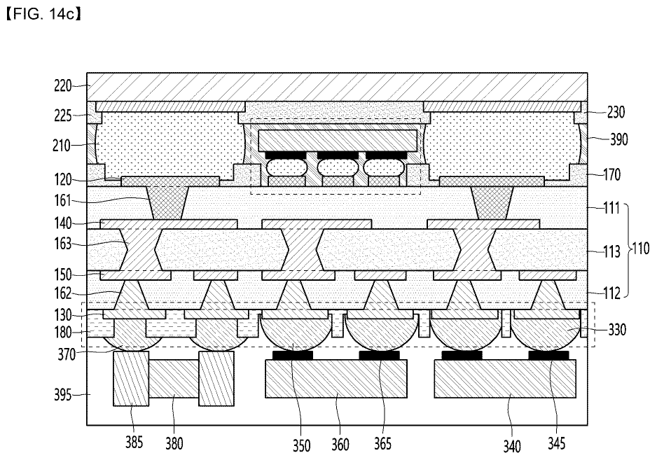

FIG. 13 is a drawing showing a semiconductor package according to a first embodiment, FIG. 14a is a drawing showing a semiconductor package according to a second embodiment, FIG. 14b is a drawing showing a semiconductor package according to a third embodiment, and FIG. 14c is a drawing showing a semiconductor package according to a fourth embodiment.

Referring to FIG. 13, the semiconductor package includes the circuit board 100 of FIG. 2. The semiconductor package of the first embodiment may have a structure in which a plurality of chips and a first external substrate are coupled on the circuit board 100. At this time, the plurality of chips in the semiconductor package of the first embodiment may be mounted only on a lower portion of the circuit board 100.

In addition, referring to FIGS. 14a and 14c, the semiconductor package may have a structure in which chips are further mounted on an upper portion of the circuit board.

Referring to FIG. 13 and FIG. 14a, the semiconductor package may include a first connection part 310 disposed on a portion of a pad of the first circuit layer 120. The first connection part 310 may have a hexahedral shape. For example, a cross-section of the first connection part 310 may include a square shape. The cross-section of the first connection part 310 may include a rectangle or a square. For example, the first connection part 310 may include a spherical shape. For example, a cross-section of the first connection part 310 may include a circular shape or a semicircular shape. For example, a cross-section of the first connection part 310 may include a partially or entirely rounded shape. The cross-sectional shape of the first connection part 310 may be flat at one side and curved at another side. The first connection part 310 may be a solder ball, but is not limited thereto.

The semiconductor package may include a first chip 320 disposed on a first connection part 310. The first chip 320 may include a terminal 325. The terminal 325 of the first chip 320 may be electrically connected to a pad of a first circuit layer 120 through the first connection part 310.

The semiconductor package may include a second connection part 330 disposed under pads of a first group of a second circuit layer 130. In addition, a second chip 340 may be mounted on the second connection part 330. The second chip 340 may include a terminal 345. The terminal 345 of the second chip 340 may be electrically connected to pads of the first group through the second connection part 330.

The semiconductor package may include a third connection part 350 disposed under pads of the second group of the second circuit layer 130. In addition, a third chip 360 may be mounted on the third connection part 350. The third chip 360 may include a terminal 365. The terminal 365 of the third chip 360 may be electrically connected to the pads of the second group through the third connection part 350.

The semiconductor package may include a fourth connection part 370 disposed under pads of the third group of the second circuit layer 130. In addition, a fourth chip 380 may be mounted on the fourth connection part 370. The fourth chip 380 may include a terminal 385. The terminal 385 of the fourth chip 380 may be electrically connected to the pads of the third group through the fourth connection part 370.

At least one of the first chip 320, the second chip 340, the third chip 360, and the fourth chip 380 may include a logic chip. For example, at least one of the first chip 320, the second chip 340, the third chip 360, and the fourth chip 380 may include an application processor chip. For example, at least one of the first chip 320, the second chip 340, the third chip 360, and the fourth chip 380 may include an analog-to-digital converter or an ASIC (application-specific IC). For example, at least one of the first chip 320, the second chip 340, the third chip 360, and the fourth chip 380 may include a memory chip. The memory chip may be a stacked memory such as HBM. For example, the memory chip may include a volatile memory (e.g., DRAM), a non-volatile memory (e.g., ROM), a flash memory, etc. In addition, at least one of the first chip 320, the second chip 340, the third chip 360, and the fourth chip 380 may include at least one of a drive IC chip, a diode chip, a power IC chip, a touch sensor IC chip, a multi-layer ceramic condenser (MLCC) chip, a ball grid array (BGA) chip, and a chip capacitor. For example, at least one of the first chip 320, the second chip 340, the third chip 360, and the fourth chip 380 may be an active device, and at least other one of the first chip 320, the second chip 340, the third chip 360, and the fourth chip 380 may be a passive device.

In addition, the semiconductor package may include a connecting member 210. The connecting member 210 may be disposed on a pad of the first circuit layer 120.

The semiconductor package may include a first external substrate 220 disposed on the connecting member 210. The first external substrate 220 may be a main board. For example, the first external substrate 220 may be a motherboard of an electronic device. The electrode 225 of the first circuit substrate 220 may be connected to the first circuit layer 120 through the connecting member 210.

The first external substrate 220 may include a third protective layer 230. The third protective layer 230 may include an opening that opens at least a portion of a lower surface of an electrode 225 provided on the first external substrate 220.

The opening provided in the third protective layer 230 may have an SMD type. A width W5 of the opening provided in the third protective layer 230 may be different from the width W3 of the opening provided in the first protective layer 170. Preferably, the width W5 of the opening provided in the third protective layer 230 may be greater than the width W3 of the opening provided in the first protective layer 230. For example, the width W5 of the opening provided in the third protective layer 230 can satisfy a range of 110% to 160%, a range of 115% to 155%, or a range of 120% to 150% of the width W5 of the opening provided in the first protective layer 230. Through this, the embodiment allows the connecting member 210 coupling the first external substrate 220 and the circuit board to be stably disposed between the first external substrate 220 and the circuit board. For example, the embodiment can minimize the occurrence of cracks in the connecting member 210. Furthermore, the embodiment can solve a problem of short circuits in which a plurality of connecting members 210 are connected to each other due to diffusion or spread of the connecting member 210.

That is, the semiconductor package includes a first protective layer 170, a second protective layer 180, and a third protective layer 230, and each protective layer includes an opening. In addition, the opening provided in the first protective layer 230 may have a first type, and the opening provided in the second protective layer 180 and the third protective layer 230 may have a second type of SMD type different from the first type.

The semiconductor package may include a first molding layer 390.

The first molding layer 390 may mold the first chip 320 and the connecting member 210.

The semiconductor package may include a second molding layer 395.

The second molding layer 395 may be disposed on a lower surface of the second insulating layer 112. The second molding layer 395 may mold the second chip 340, the third chip 360, and the fourth chip 380.

The first molding layer 390 and the second molding layer 395 may be, but are not limited to, EMC (Epoxy Mold Compound).

At this time, the first molding layer 390 and the second molding layer 395 may have a low dielectric constant in order to increase heat dissipation characteristics. For example, the dielectric constant (Dk) of the first molding layer 390 and the second molding layer 395 may be 0.2 to 10. For example, the dielectric constant (Dk) of the first molding layer 390 and the second molding layer 395 may be 0.5 to 8. For example, the dielectric constant (Dk) of the first molding layer 390 and the second molding layer 395 may be 0.8 to 5. Accordingly, in the embodiment, the first molding layer 390 and the second molding layer 395 have low dielectric constants, so that heat generated from the first to fourth chips 320, 340, 360, and 380 can be efficiently dissipated to an outside.

Referring to FIG. 14b, the semiconductor package of the third embodiment may have a different type of opening provided in the second protective layer compared to the semiconductor package of the first embodiment of FIG. 14a.

That is, the semiconductor package of the third embodiment may include a second protective layer 180A.

That is, the second protective layer 180A may include an opening that vertically overlaps a circuit layer on which a chip is mounted. At this time, the opening of the second protective layer provided in the semiconductor package of FIG. 14a has an SMD type.

In contrast, the second protective layer 180A provided in the semiconductor package of the third embodiment may have a same type as the opening provided in the first protective layer 170.

Through this, in a process of forming an opening in the first protective layer 170, the embodiment may form an opening in the second protective layer 180A to correspond to the opening in the first protective layer 170. Through this, the embodiment may form an opening by simultaneously processing the first protective layer 170 and the second protective layer 180A, thereby improving processability and achieving process simplification.

Referring to FIG. 14c, the semiconductor package of the fourth embodiment may have different shapes of the opening provided in the first protective layer 170 and the opening provided in the second protective layer 180 compared to FIGS. 14a and 14b.

For example, the first protective layer 170 may be provided with a plurality of openings. The plurality of openings may include a first opening vertically overlapping the first connection part 310 and a second opening vertically overlapping the connecting member 210.

In addition, the first opening of the first protective layer 170 may open an entire region where the first connection part 310 is disposed. For example, the first protective layer 170 may open an entire region of the first circuit layer 120 that is connected to the terminal 325 of the first chip 320. For example, the plurality of pads may be commonly opened through one first opening provided in the first protective layer 170. Therefore, the plurality of pads connected to the terminal 325 of the first chip 320 and an insulating layer region provided between the plurality of pads may be commonly opened through one first opening.

Meanwhile, a second opening of the first protective layer 170 may have a first type as described.

In addition, the second protective layer 180 may include a plurality of openings having different shapes.

For example, the second protective layer 180 may include a first opening of the first type, a second opening of the second type, and a third opening of the third type. The second type may be an SMD type, and the third opening may be an NSMD type. In addition, the first type may be an NSMD-like type in which a part of the side surface of the circuit layer is covered with the second protective layer 180 while having an NSMD type.

That is, the embodiment may apply different types of opening of the protective layer according to the type of chip to be mounted and/or the type of external substrate to be connected. Accordingly, the embodiment may improve the degree of design freedom of the circuit board and the semiconductor package including the same.

FIG. 15 is a cross-sectional view showing a semiconductor package according to a fifth embodiment.

Referring to FIG. 15, the semiconductor package according to the fifth embodiment may have a structure in which a second external substrate 420 is additionally disposed in the semiconductor package of the second embodiment.

To this end, the second circuit layer 120 of the circuit layer 120 may include a post bump 135. In addition, a sixth connection part 410 may be disposed on a lower surface of the post bump 135.

To this end, the second molding layer 395 may include an open region opening a lower surface of the post bump 135.

A second external substrate 4520 may be coupled to the sixth connection part 410. The second external substrate 4520 may be a memory package. To this end, the second external substrate 420 may include a memory chip 430.

However, the embodiment is not limited thereto, and the second external substrate 420 may be an interposer disposed between a memory package and the post bump 135.

At this time, the second protective layer 180 of the fifth embodiment may include different types of first openings and second openings. For example, the second protective layer 180 may include a first opening corresponding to a region where the post bump 135 is disposed. In addition, the first opening of the second protective layer 180 may have an SMD type. In addition, the second protective layer 180 may include a second opening corresponding to a region where the chip is disposed. In addition, the second opening of the second protective layer 180 may have an NSMD type or NSMD-like type, not an SMD type.

### Manufacturing Method of Circuit Board

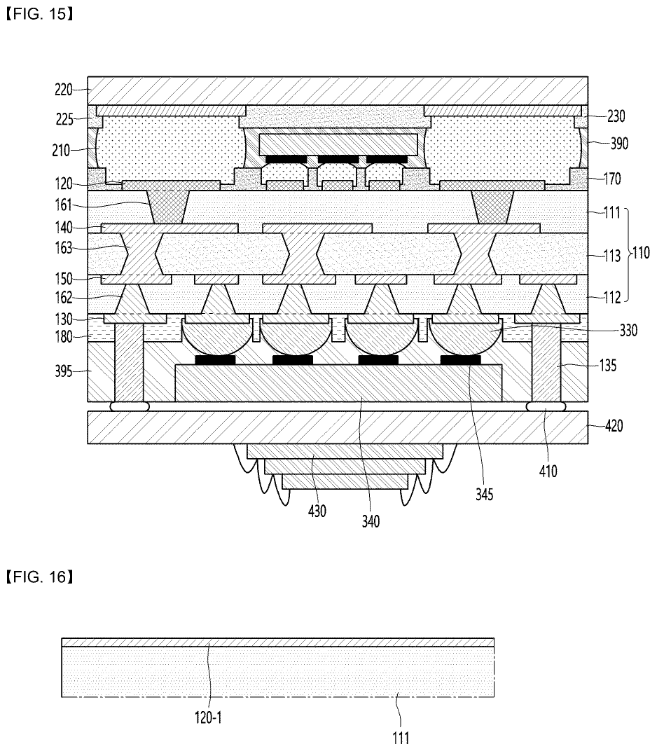

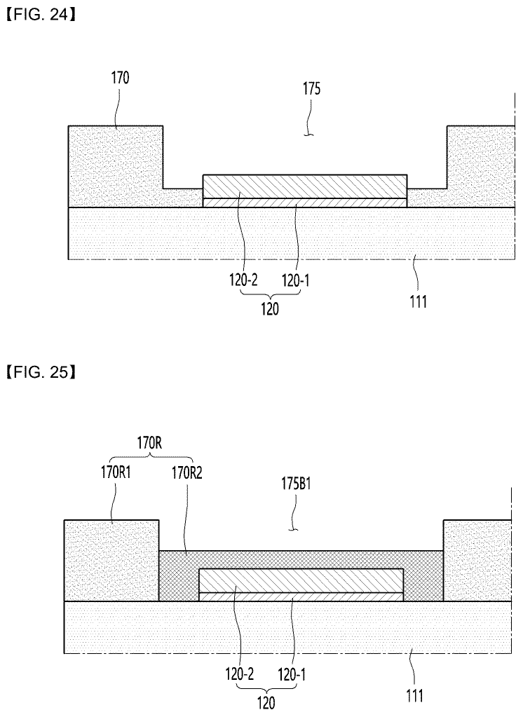

FIGS. 16 to 24 are drawings for explaining a method for manufacturing a circuit board of the first embodiment shown in FIG. 2 in order of processes. In addition, FIGS. 25 to 28 are drawings for explaining a method for manufacturing a circuit board of the third embodiment shown in FIG. 10 in order of processes.

In addition, a process of forming the first circuit layer 120 and the first protective layer 170 at an upper side of the first insulating layer 111 in the circuit board will be described below.

Referring to FIG. 16, the embodiment prepares the first insulating layer 111. Preferably, a step of preparing the first insulating layer 111 may mean a process of laminating the first insulating layer 111 on the third insulating layer 113 while a third circuit layer 140 is disposed on the third insulating layer 113. Next, the embodiment may form the first metal layer 120-1 on the first insulating layer 111. The first metal layer 120-1 may mean a copper layer disposed on the first insulating layer 111. In contrast, the first metal layer 120-1 may be an electroless plating layer formed by performing electroless plating on the first insulating layer 111. For example, the first metal layer 120-1 may be a chemical copper plating layer. In contrast, the first metal layer 120-1 may include both a copper foil layer and a chemical copper plating layer.

Next, referring to FIG. 17, the embodiment forms a first mask M1 on the first metal layer 120-1. The first mask M1 may include an open region OR1 that opens a region where the first circuit layer 120 is to be formed.

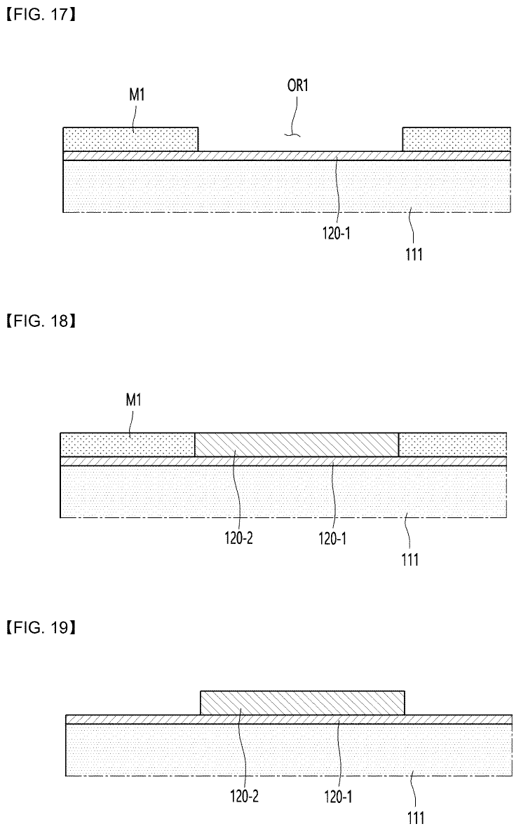

Next, referring to FIG. 18, the embodiment forms a second metal layer 120-2 that fills the open region OR1 of the first mask M1 using the first metal layer 120-1 as a seed layer.

Next, referring to FIG. 19, the embodiment can perform a process of removing the first mask M1.

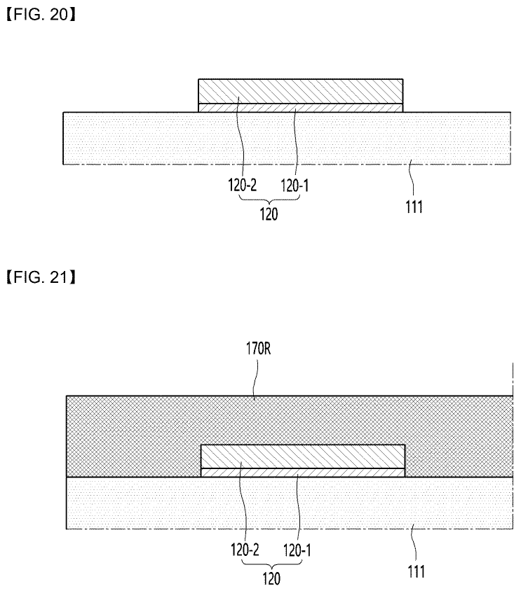

Next, referring to FIG. 20, the embodiment can perform a process of removing a portion of the first metal layer 120-1 that does not vertically overlap with the second metal layer 120-2 by etching.

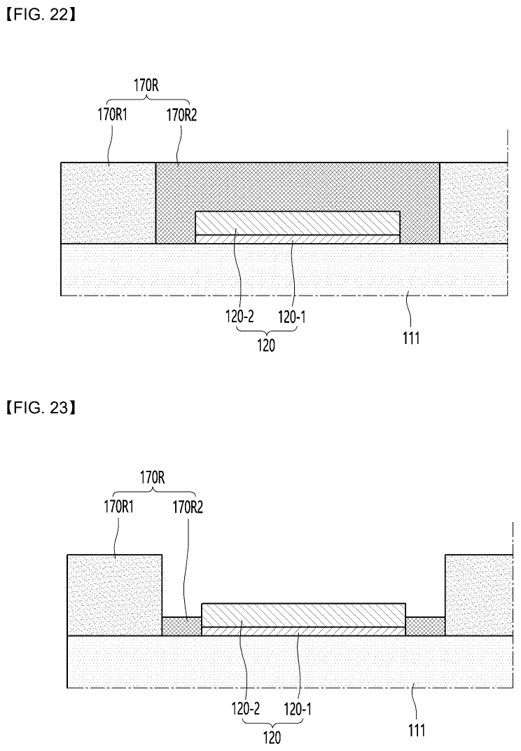

Next, referring to FIG. 21, the embodiment can perform a process of forming a first resist layer 170R on the first insulating layer 111. The first resist layer 170R may refer to a layer before the opening 175 is formed in the first protective layer 170 of the embodiment.

Next, referring to FIG. 22, the embodiment can perform a process of partially exposing the first resist layer 170R. Through this, the embodiment can perform a process of partially curing the first resist layer 170R. Specifically, the embodiment may allow the first resist layer 170R to include a first region 170R1 that is cured by exposure and an uncured second region 170R2.

Next, referring to FIG. 23, the embodiment may perform a removal process for thinning a thickness of the uncured second region 170R2. Specifically, the embodiment may perform a removal process for thinning a thickness of the uncured second region 170R2 using an organic alkaline compound containing tetramethylammonium hydroxide (TMAH) or trimethyl-2-hydroxyethylammonium hydroxide (choline). At this time, the embodiment may not completely remove the second region 170R2. Specifically, the embodiment may allow at least a portion of the second region 170R2 to remain on the first insulating layer 111 through the removal process for thinning the thickness.

Next, referring to FIG. 24, the embodiment may end the thinning removal process when the second region 170R2 has a desired thickness by the thinning removal process, and may proceed with a process of curing the second region 170R2 that has not been removed accordingly. Through this, the embodiment may dispose the first protective layer 170 provided with the opening 175 on the first insulating layer 111.

Meanwhile, the embodiment may perform the removal process for thinning the thickness multiple times so that the first protective layer has an opening with a step.

Specifically, referring to FIG. 25, the embodiment may perform a process of forming the first part 175B1 of the opening 175B in the second region 170R2 by performing a first removal process for thinning.

Thereafter, referring to FIG. 26, the embodiment may perform a process of partially exposing and curing the second region 170R2. Through this, the second region 170R2 may include an exposed and cured second-first region 170R21 and an uncured second-second region 170R2-2.

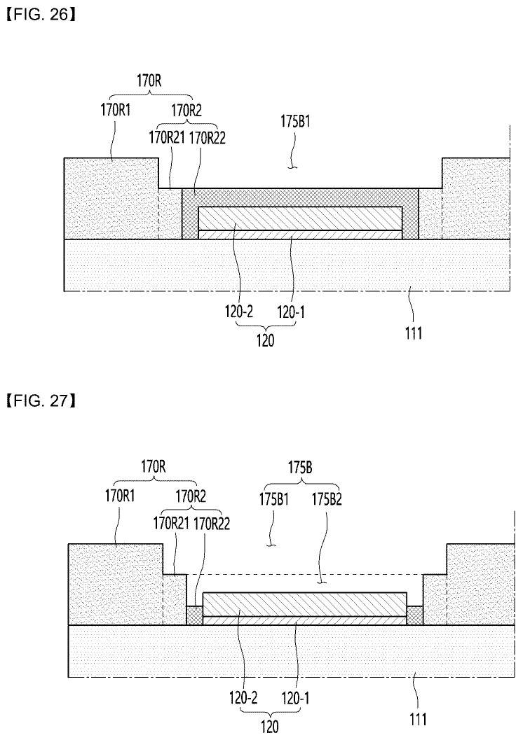

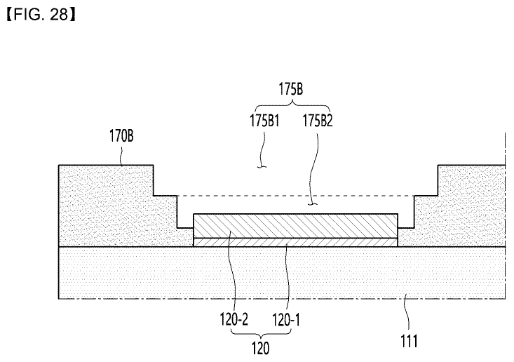

Next, referring to FIG. 27, the embodiment may perform a second removal process of thinning a thickness of the second-second region 170R2-2 to form a second part 175B2 connected to the first part 175B1.

Next, referring to FIG. 28, the embodiment may perform a process of curing the second-second region 170R2-2 when the second-second region 170R2-2 is removed to a desired thickness. Accordingly, in the embodiment, a first protective layer 170C equipped with an opening 175B having a step can be disposed on a first insulating layer 111.

On the other hand, when the circuit board having the above-described characteristics of the invention is used in an IT device or home appliance such as a smart phone, a server computer, a TV, and the like, functions such as signal transmission or power supply can be stably performed. For example, if a circuit board having the features of the present invention performs a semiconductor package function, the circuit board can function to safely protect the semiconductor device from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor device. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1-10. (canceled)

11. A circuit board comprising:
a build-up insulating layer including a plurality of insulating layers laminated along a vertical direction;
a protective layer disposed on the build-up insulating layer and having a recess concaved from an upper surface toward a lower surface; and
a circuit layer disposed on the build-up insulating layer and penetrating a bottom surface of the recess of the protective layer, and
wherein an inner surface of the recess includes a first inner surface connected to the bottom surface and having a first slope, and a second inner surface provided on the first inner surface and having a second slope different from the first slope.

12. The circuit board of claim 11, wherein the first slope with respect to the bottom surface is greater than the second slope with respect to the bottom surface.

13. The circuit board of claim 12, wherein the first slope with respect to the bottom surface is greater than 90°, and
wherein the second slope with respect to the bottom surface is 90° or less.

14. The circuit board of claim 11, wherein a width of the recess in a horizontal direction is greater than a width of the circuit layer in the horizontal direction.

15. The circuit board of claim 11, wherein the upper surface of the protective layer is positioned higher than an upper surface of the circuit layer based on an upper surface of the build-up insulating layer.

16. The circuit board of claim 11, wherein the bottom surface of the recess is positioned between an upper surface of the circuit layer and a lower surface of the circuit layer.

17. The circuit board of claim 11, wherein the first inner surface overlaps the circuit layer along a horizontal direction.

18. The circuit board of claim 17, wherein the inner surface of the recess further includes a contact portion where the first inner surface and the second inner surface contact each other, and
wherein the contact portion overlaps the circuit layer along the horizontal direction.

19. The circuit board of claim 11, wherein the circuit layer includes a pad portion overlapping the recess along the vertical direction, and
wherein the protective layer is provided to cover at least a portion of a side surface of the pad portion.

20. The circuit board of claim 19, wherein the pad portion includes a plurality of upper pads spaced apart from each other along a horizontal direction, and
wherein a separation distance in the horizontal direction between the plurality of upper pads satisfies a range of 20% to 90% of a width of each of the plurality of upper pads.

21. The circuit board of claim 19, a width in a horizontal direction of the recess of the protective layer satisfies a range of 105% to 150% of a width in the horizontal direction of the pad portion.

22. The circuit board of claim 11, wherein a vertical distance from the lower surface of the protective layer to the bottom surface of the recess satisfies a range of 20% to 90% of a thickness of the circuit layer.

23. The circuit board of claim 20, wherein a horizontal distance from the second inner surface of the protective layer to a side surface of the upper pad closest to the second inner surface satisfies a range of 5% to 45% of the separation distance.

24. The circuit board of claim 11, wherein the protective layer includes a first protective member disposed on the build-up insulating layer, and a second protective member disposed on the first protective member,
wherein the recess is provided at an upper surface of the first protective member, and
wherein the second protective member includes a through hole overlapping the recess along the vertical direction.

25. The circuit board of claim 24, wherein a width of the recess in a horizontal direction is smaller than a width of the through hole in the horizontal direction.

26. The circuit board of claim 11, further comprising:
a semiconductor chip disposed on the protective layer.

27. The circuit board of claim 11, further comprising:
an external substrate disposed on the protective layer.

28. The circuit board of claim 11, wherein the first slope with respect to the bottom surface is smaller than the second slope with respect to the bottom surface.

29. The circuit board of claim 28, wherein a horizontal distance from a side surface of the circuit layer to the first inner surface is greater than a horizontal distance from the side surface of the circuit layer to the second inner surface.

30. The circuit board of claim 28, wherein a lower end of the first inner surface is positioned lower than at least a portion of the bottom surface based on an upper surface of the build-up insulating layer.
